(19) United States
(12) Patent Application Publication
(10) Pub. No.: US 2005/0120961 A1
(43) Pub. Date: Jun. 9, 2005

(54) Rapid thermal processing system, method for manufacuturing the same, and method for adjusting temperature

(75) Inventor: Hiroko Kubo, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/005,003

(22) Filed: Dec. 7, 2004

(30) Foreign Application Priority Data
Dec. 8, 2003 (JP) 2003-408769

(51) Int. Cl. C23C 16/00

(52) U.S. Cl. 118/728

(57) ABSTRACT

Using a rapid thermal processing system provided with a substrate carrier supporting a substrate and having oxidation resistance, rapid thermal processing is carried out on the substrate.

### CROSS-REFERENCE TO RELATED APPLICATIONS

This application claims priority under 35 U.S.C. § 119 on Patent Application No. 2003-408769 filed in Japan on Dec. 8, 2003, the entire contents of which are hereby incorporated by reference.

### BACKGROUND OF THE INVENTION

(a) Fields of the Invention

The present invention relates to rapid thermal processing systems for carrying out rapid thermal processing on a substrate, methods for manufacturing such a system, and methods for adjusting the temperature of the substrate in the rapid thermal processing system.

(b) Description of Related Art

Recently, miniaturization and high degree of integration of semiconductor elements have rapidly been developed, and the diameter of a substrate (wafer) has increasingly become greater. Accompanied with these trends, a conventional batch processing for processing a plurality of substrates at a time is shifting to a single wafer processing.

In a thermal processing process of a substrate, in response to demands for reduction of thermal budgets and formation of shallow junctions, rapid thermal processing (RTP) is coming into widespread use.

FIG. 21 is a view showing a schematic structure of a conventional rapid thermal processing system operating in a single wafer processing system (see Japanese Unexamined Patent Publication No. H10-173032 (FIG. 3 and page 6)).

In a process chamber 1 of the rapid thermal processing system shown in FIG. 21, the end (edge) of a substrate 10 is carried by an annular substrate carrier 2. The substrate carrier 2 is placed in the bottom portion within the process chamber 1 with a rotating unit 3 interposed therebetween. The upper portion of the process chamber 1 is provided with a heating unit 4, and a portion within the process chamber 1 located under the substrate 10 is provided with optical pyrometers 5 so that the optical pyrometers 5 are not in direct contact with the substrate 10. The heating unit 4 and the optical pyrometers 5 ate controlled by a control system 6 provided outside the process chamber 1. The portion within the process chamber 1 located under the substrate 10 is provided with a reflecting plate 7 for improving the accuracy of temperature measurement by the optical pyrometers 5.

In a rapid thermal processing carried out in a single wafer processing system, generally, a substrate alone is heated at a temperature rise rate as high as tens to hundreds of degrees Celsius per second (° C./sec). Thus, the processing time is several seconds to hundreds of seconds, which is dramatically reduced as compared to a conventional thermal processing using an electric furnace or the like. From this, in the case of an inadequate control of the processing temperature, the difference in temperature is widened within the surface of the substrate 10 during the thermal processing, which causes bowing of the substrate 10 or slips 11 in the perimeter of the substrate 10 as shown in FIG. 22. In some instance, this may bring about cracking of the substrate or other troubles, and eventually production yields are significantly reduced. Such a tendency is more significant with an increase in diameter of the substrate.

As mentioned above, in a rapid thermal processing system, an optical pyrometer (pyrometer) is widely used to measure the temperature therein. The optical pyrometer is an instrument for measuring a temperature utilizing the properties that “an object with a fixed temperature emits radiation with specific spectrum and intensity”, and it measures radiation emitted by the object to determine (estimate) the temperature of the measured object. As is expected easily from the utilization of radiation, the optical pyrometer is greatly affected by the emissivity of a target object, so that a change in the emissivity of the object due to the rapid thermal processing becomes a major contributor to a shift of the temperature measured by the optical pyrometer.

To avoid such a problem, a rapid thermal processing system is proposed in which a plurality of optical pyrometers sequentially measure temperatures of respective points within the substrate surface and in a thermal processing mechanism in the system, the temperatures of thermal processing units (subsystems) associated with the respective optical pyrometers (that is, the points to be measured within the substrate) are independently controlled.

However, if the conventional rapid thermal processing system is provided with a substrate carrier for carrying the substrate edge and an optical pyrometer for measuring the temperature around the substrate edge, the optical pyrometer is affected by thermal radiation not only from the substrate 10 but also from the substrate carrier 2 as shown in FIG. 23. In other words, a difference in temperature occurs not only within the surface of the substrate 10 but also between the edge of the substrate 10 and the substrate carrier 2. As a result of this, the optical pyrometer cannot measure the exact temperature of the substrate, and an inexact measurement temperature thereof is transferred to the thermal processing mechanism. Moreover, if the emissivity of the substrate carrier fluctuates or other phenomena occur with repetitions of the thermal processing, the optical pyrometer determines that the substrate temperature varies gradually by each thermal processing due to influences of the substrate carrier. This may provide a temperature control system including the thermal processing mechanism with information on the temperature that varies with time.

To suppress the occurrence of slips or the like that will significantly degrade production yields, it is very important to control the temperature of the substrate edge with high precision. However, as described above, in the case where an accurate temperature measurement cannot be performed due to the influences of the substrate carrier, the highly precise temperature control of the substrate edge is extremely difficult to carry out.

### SUMMARY OF THE INVENTION

The present invention has been made to solve the conventional problems described above, and an object thereof is to provide an excellent rapid thermal processing system capable of dramatically boosting yields of devices by improving the controllability of the temperature of the rapid thermal processing system, a method for manufacturing such a system, and a method for adjusting the temperature in the system.

To attain the above object, a rapid thermal processing system according to the present invention is designed for carrying out rapid thermal processing on a substrate. The system comprises a substrate carrier for supporting the substrate. The substrate carrier has oxidation resistance.

With the rapid thermal processing system of the present invention, since the substrate carrier has oxidation resistance, it becomes difficult to oxidize or oxynitride the substrate carrier even if the processing is carried out either at a relatively high temperature or in an atmosphere having a relatively strong ability of oxidization or oxynitriding. Therefore, a change in the emissivity of the substrate carrier during the processing can be suppressed. This avoids the determination by an optical pyrometer provided around the edge of the substrate that the substrate temperature is changed with time due to influences of the substrate carrier. That is to say, the temperature around the substrate edge can be accurately transferred to a temperature control system including a thermal processing mechanism. Consequently, the temperature controllability around the substrate edge can be improved to suppress slips or the like in the substrate, which dramatically boosts yields of devices to be processed.

In the rapid thermal processing system of the present invention, the substrate carrier may contain an element forming the substrate such as silicon.

Preferably, in the rapid thermal processing system of the present invention, the oxidation resistance is imparted to the substrate carrier by nitriding, oxidizing, or oxynitriding a component of the carrier.

This ensures impartation of the oxidation resistance to the substrate carrier.

Preferably, in the rapid thermal processing system of the present invention, the oxidation resistance is imparted only to a portion of the substrate carrier exposed to an atmosphere during the rapid thermal processing.

With this system, since a change in the emissivity of the substrate carrier by the rapid thermal processing can be suppressed certainly, the temperature around the substrate edge can be measured accurately without changing with time. Therefore, the thermal processing carried out on the substrate edge and its vicinity will not vary with time.

Furthermore, since a portion of the substrate carrier not exposed to an atmosphere during the rapid thermal processing has the properties of the original material of the substrate carrier, the heat emissivity of the substrate carrier is nearly invariable before and after impartation of oxidation resistance to the substrate carrier. Therefore, for example, even if the temperature condition (the setting condition or the like) of the rapid thermal processing system has been adjusted using the substrate carrier before the impartation of oxidation resistance to the substrate carrier, the adjusted temperature condition can be put to use with very little adjustment.

Moreover, the heat dissipation capability of the connecting portion between the substrate carrier and the mechanism for supporting the carrier (for example, a rotating unit attached to the bottom of a chamber) is nearly invariable before and after impartation of oxidation resistance to the substrate carrier, so that the cooling efficiency of the rapid thermal processing system is kept in the original condition.

Furthermore, only the portion of the substrate carrier exposed to an atmosphere during the rapid thermal processing has oxidation resistance to provide the following effects. If, for example, the mechanism for supporting the substrate carrier is the rotating unit and the substrate carrier is in synchronization with the rotating unit, the contact portion between the substrate carrier and the rotating unit has to be kept at an appropriate friction coefficient. Specifically, in the case where this portion has an inappropriate friction coefficient, although the rotating unit is rotating, the substrate carrier slips on the rotating unit and a normal rotation of the substrate carrier, that is, the substrate cannot be accomplished. In addition to this, by the slipping, a mechanically polishing (rubbing action) arises at the contact point (the contact line) between the substrate carrier and the rotating unit, and thus the contact point (the contact line) may become a source of particles or the like. As can be apparent from this, the friction coefficient of the portion of the substrate carrier in contact with the rotating unit (mechanism for supporting the substrate carrier) has to be large enough to have the ability to bear rotational inertia (centrifugal force), and generally the original substrate carrier (the substrate carrier without resistance to oxidation) is designed to meet this demand. On the other hands, if the oxidation resistance is imparted to this contact portion and the friction coefficient of this portion is changed, a newly caused trouble (occurrence of particles or the like) would occur even though the above problem can be solved. However, the region of the substrate carrier containing the contact point (contact line) with the mechanism for supporting the substrate carrier and not exposed to an atmosphere during rapid thermal processing does not have oxidation resistance imparted and is kept in the surface condition of the original substrate carrier, thereby solving the problems without causing any new troubles.

A method for manufacturing a rapid thermal processing system according to the present invention is a method for manufacturing the rapid thermal processing system of the present invention in the case where the oxidation resistance is imparted to the substrate carrier by nitriding, oxidation, or oxynitriding. In this method, the nitriding, oxidation, or oxynitriding of the component of the substrate carrier is carried out using the rapid thermal processing system or another rapid thermal processing system.

With the method for manufacturing a rapid thermal processing system according to the present invention, the nitriding, oxidation, or oxynitriding of the component of the substrate carrier is carried out using the rapid thermal processing system of the present invention or another rapid thermal processing system. Therefore, oxidation resistance can be imparted only to a portion of the substrate carrier expected to be exposed to an atmosphere during the rapid thermal processing (that is, a portion thereof probably causing a change in substrate temperature with time). This provides the above effects exerted in the case where oxidation resistance is imparted only to the portion of the substrate carrier exposed to an atmosphere during the rapid thermal processing.

A temperature adjustment method according to the present invention is designed for adjusting the temperature of a substrate in a rapid thermal processing system for carrying out rapid thermal processing on the substrate. The rapid thermal processing system comprises: a substrate carrier for supporting the substrate; and a plurality of optical pyrometers for measuring the temperature of the substrate during the rapid thermal processing. The plurality of optical pyrometers are disposed at least in a center portion and an edge portion of the substrate so that the pyrometers are not in direct contact with the substrate. The temperature adjustment method comprises the steps of acquiring the quantity of temperature dependence by carrying out rapid thermal processing on the substrate; and independently correcting temperature shifts of the individual optical pyrometers based on the acquired quantity of temperature dependence.

In the temperature adjustment method of the present invention, the quantity of temperature dependence is acquired by carrying out rapid thermal processing on the substrate, and then temperature shifts of the individual optical pyrometers are independently corrected based on the acquired quantity of temperature dependence. That is to say, utilizing the fact that the difference in the quantity of temperature dependence within the substrate surface corresponds to the temperature shift, the measurement temperatures of the optical pyrometers can be corrected so that the quantity of temperature dependence has a value corresponding to a desired temperature. Therefore, the temperature shifts within the substrate surface caused by the rapid thermal processing can be made uniform with high precision. Accordingly, the temperature controllability can be improved even around the substrate edge to suppress slips or the like in the substrate, which dramatically boosts yields of devices to be processed.

In the temperature adjustment method of the present invention, if the quantity of temperature dependence is the amount of slips occurring in the substrate, the effects described above can be attained certainly.

In the temperature adjustment method of the present invention, if the quantity of temperature dependence is the thickness of a film formed by carrying out rapid thermal processing on the substrate, the effects described above can be attained certainly. In this case, the step of correcting temperature shifts may include the substep of correcting the temperature shifts to satisfy 0.4×B<A<B (where A is the average thickness of the film measured at multiple points located within an outer perimeter region of the substrate with a width of 10% of the radius of the substrate, and B is the average thickness of the film measured at multiple points within a region of the substrate located radially inwardly from the outer perimeter region).

Preferably, in the temperature adjustment method of the present invention, the step of acquiring the quantity of temperature dependence includes the substep of carrying out rapid thermal processing on the substrate under a reduced pressure.

This provides the following effects. Since, in the case of the rapid thermal processing under a reduced pressure, the cooling efficiency after the rapid thermal processing is poorer than the processing under an atmospheric pressure, the heat dissipation efficiencies of the substrate and the substrate carrier are significantly lowered. As a result, the substrate carrier having insufficiently been cooled is used for the processing of the next substrate, so that the temperature difference between the substrate carrier and the substrate edge tends to be large to cause the problem that slips occur easily. On the other hands, acquirement of the quantity of temperature dependence for correcting temperature shifts is carried out under a reduced pressure identical to the actual processing, whereby the accuracy of the temperature correction can be dramatically improved to prevent the above problem, that is, the occurrence of slips.

In the temperature adjustment method of the present invention, if the quantity of temperature dependence is the thickness of a film formed by carrying out rapid thermal processing on the substrate, the film is preferably an oxide film and the step of acquiring the quantity of temperature dependence preferably includes the substep of carrying out rapid thermal processing on the substrate under a reduced pressure.

This provides the following effects. Since, in the case of the rapid thermal processing under a reduced pressure, the cooling efficiency after the rapid thermal processing is poorer than the processing under an atmospheric pressure, the heat dissipation efficiencies of the substrate and the substrate carrier are significantly lowered. As a result, the substrate carrier having insufficiently been cooled is used for the processing of the next substrate, so that the temperature difference between the substrate carrier and the substrate edge tends to be large to cause the problem that slips occur easily. On the other hands, acquirement of the quantity of temperature dependence (that is, the thickness of the oxide film) for correcting temperature shifts is carried out under a reduced pressure identical to the actual processing, whereby the accuracy of the temperature correction can be dramatically improved to prevent the above problem, that is, the occurrence of slips.

In the temperature adjustment method of the present invention, the rapid thermal processing system may be the rapid thermal processing system of the present invention, and the substrate carrier may have oxidation resistance.

As described above, the present invention relates to rapid thermal processing systems for carrying out rapid thermal processing on a substrate, methods for manufacturing such a system, and methods for adjusting the temperature of the substrate in the rapid thermal processing system, and is useful especially for application to fabrication of an electronic device such as a semiconductor device.

To be more specific, with the present invention, since a substrate carrier of the rapid thermal processing system has oxidation resistance, it becomes difficult to oxidize or oxynitride the substrate carrier even if the processing is carried out either at a relatively high temperature or in an atmosphere having a relatively strong ability of oxidization or oxynitriding. Therefore, a change in the emissivity of the substrate carrier during the processing can be suppressed. This accurately transfers the temperature around the edge of a substrate to a temperature control system including a thermal processing mechanism. As a result, the temperature controllability around the substrate edge can be improved to suppress slips or the like in the substrate, which dramatically boosts yields of devices to be processed.

Moreover, in the present invention, the quantity of temperature dependence is acquired by carrying out rapid thermal processing on the substrate, and then temperature shifts of individual optical pyrometers are independently corrected based on the acquired quantity of temperature dependence. Therefore, the measurement temperatures of the optical pyrometers can be corrected so that the quantity of temperature dependence has a value corresponding to a desired temperature, so that the temperature shifts within the substrate surface caused by the rapid thermal processing can be made uniform with high precision. Accordingly, the temperature controllability can be improved even around the substrate edge to suppress slips or the like in the substrate, which dramatically boosts yields of devices to be processed.

### BRIEF DESCRIPTION OF THE DRAWINGS

FIG. 1A is a view showing a schematic structure of a rapid thermal processing system according to a first embodiment of the present invention, and FIG. 1B is a view showing a sectional structure of a substrate carrier of the rapid thermal processing system according to the first embodiment of the present invention.

FIGS. 2A to 2D are views showing a variety of plan configurations of substrate carriers of rapid thermal processing systems according to first to fourth embodiments of the present invention, respectively, in which each substrate carrier has a shelf

FIGS. 3A to 3C are views showing a variety of plan configurations of substrate carriers of the rapid thermal processing systems according to the first to fourth embodiments of the present invention, respectively, in which each substrate carrier has a shelf.

FIG. 4 is a view showing a schematic sectional structure taken along the line A-A of each of FIGS. 2A to 2D and FIGS. 3A to 3C.

FIG. 5 is a view showing a sectional structure of the substrate carrier of the rapid thermal processing system according to the second embodiment of the present invention.

FIG. 6 is a view showing a sectional structure of the substrate carrier of the rapid thermal processing system according to the third embodiment of the present invention.

FIG. 7 is a view showing a sectional structure of the substrate carrier of the rapid thermal processing system according to the fourth embodiment of the present invention.

FIGS. 8A and 8B are a graph and a view for describing a characteristic of a temperature adjustment method according to a fifth embodiment of the present invention.

FIG. 9 is a flowchart of the temperature adjustment method according to the fifth embodiment of the present invention.

FIG. 10 is a graph showing the amount of slips occurring when the temperature correction amount ΔT is changed in a temperature adjustment method according to a sixth embodiment of the present invention.

FIG. 11 is a flowchart of the temperature adjustment method according to the sixth embodiment of the present invention.

FIGS. 12A and 12B are a graph and a view for describing a characteristic of a temperature adjustment method according to a seventh embodiment of the present invention.

FIG. 13 is a flowchart of the temperature adjustment method according to the seventh embodiment of the present invention.

FIGS. 14A and 14B are a graph and a view for describing a characteristic of a temperature adjustment method according to an eighth embodiment of the present invention.

FIGS. 15A to 15C are views for describing the characteristic of the temperature adjustment method according to the eighth embodiment of the present invention.

FIG. 16 is a flowchart of the temperature adjustment method according to the eighth embodiment of the present invention.

FIG. 17 is a graph showing the amount of slips occurring when the temperature correction amount ΔT is changed in a temperature adjustment method according to a ninth embodiment of the present invention.

FIG. 18 is a flowchart of the temperature adjustment method according to the ninth embodiment of the present invention.

FIGS. 19A and 19B are a graph and a view for describing a characteristic of a temperature adjustment method according to a tenth embodiment of the present invention.

FIG. 20 is a flowchart of the temperature adjustment method according to the tenth embodiment of the present invention.

FIG. 21 is a view showing a schematic structure of a conventional rapid thermal processing system operating in a single wafer processing system.

FIG. 22 is a view showing the occurrence of slips at the perimeter of a substrate in the conventional rapid thermal processing operating in the single wafer processing system.

FIG. 23 is a view for describing a controversial point of the conventional rapid thermal processing system operating in the single wafer processing system.

### DETAILED DESCRIPTION OF THE PREFERRED EMBODIMENTS

### First Embodiment

A rapid thermal processing system according to a first embodiment of the present invention will be described below with reference to the accompanying drawings.

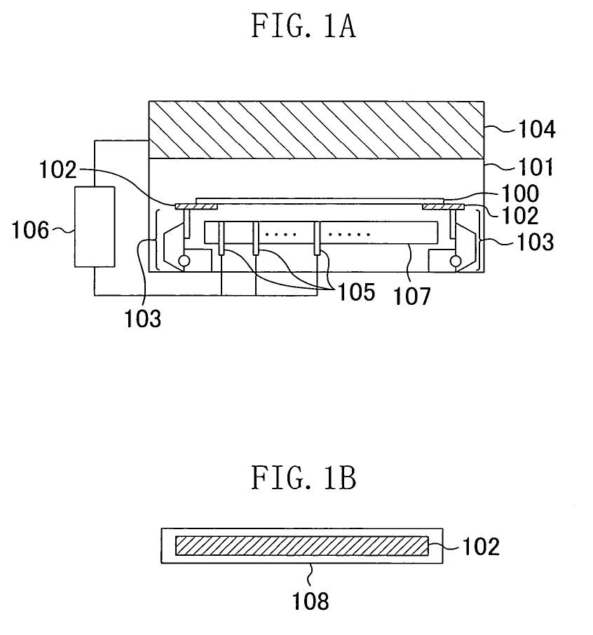

FIG. 1A is a view showing a schematic structure of the rapid thermal processing system according to the first embodiment, and FIG. 1B is a view showing a sectional structure of a substrate carrier of the rapid thermal processing system according to the first embodiment.

In a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In the first embodiment, at least one of the plurality of optical pyrometers 105 is placed around the edge of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the first embodiment is characterized in that in the rapid thermal processing system shown in FIG. 1A, the substrate carrier 102 has resistance to oxidation (the property of not or hardly being oxidized). To be more specific, as shown in FIG. 1B, the entire surfaces of the substrate carrier 102 are covered with a portion 108 having resistance to oxidation (referred hereinafter to as an oxidation resistant portion 108). By this structure, even when oxidation processing or oxynitriding processing is carried out either at a relatively high temperature of 950° C. or more or in an atmosphere having a relatively strong ability of oxidization or oxynitriding, it becomes difficult to oxidize or oxynitride the substrate carrier 102 by such a processing. Therefore, unlike the case of using the conventional substrate carrier 2, a change in properties of the substrate carrier 102, in particular a change in emissivity becomes so small as to be negligible. As a result, an accurate measurement temperature invariable with time is transferred to the control system 106 while the optical pyrometer 105 provided around the edge of the substrate 100 never determines that the temperature of the substrate carrier 102 is changed with time. This prevents the thermal processing around the edge of the substrate 100 from changing with time. That is to say, the temperature controllability around the edge of the substrate 100 can be improved to suppress slips or the like in the substrate 100, which dramatically boosts yields of devices to be processed.

In the first embodiment, impartation of oxidation resistance to the substrate carrier 102 is made by thickly oxidizing or oxynitriding in advance the surfaces of the substrate carrier 102 of, for example, silicon. Alternatively, impartation of oxidation resistance to the substrate carrier 102 may be made by depositing, to the surfaces of the substrate carrier 102, a thick oxide film (for example, a silicon oxide film) or a thick oxynitride film (for example, a silicon oxynitride film) which serves as the oxidation resistant portion 108. The reason why the thick oxide or oxynitride film can impart oxidation resistance to the substrate carrier 102 is as follows. Oxidation or oxynitriding by the rapid thermal processing does not change the thick oxide or oxynitride film, so that during the rapid thermal processing, a change in the emissivity of the substrate carrier covered with the thick oxide or oxynitride film becomes so small as to be negligible.

In the first embodiment, the entire surfaces of the substrate carrier 102 are covered with the oxidation resistant portion 108 (for example, a thick oxide film). Alternatively, only the front surface of the substrate carrier 102, properly speaking, only the surface of the substrate carrier exposed to an atmosphere during the rapid thermal processing may be covered with the oxidation resistant portion 108. In other words, the back surface of the substrate carrier 102, properly speaking, the surface of the substrate carrier 102 facing a space surrounded with the substrate 100, the substrate carrier 102, and the rotating unit 103 does not have to be covered with the oxidation resistant portion 108.

In the first embodiment, if the surfaces of the substrate carrier 102 are thickly oxidized or oxynitrided in advance to impart oxidation resistance to the substrate carrier 102, the surfaces of the substrate carrier 102 may be oxidized or oxynitrided, for example, in an atmosphere containing hydrogen and oxygen (for example, a mixed atmosphere of hydrogen and oxygen or a mixed atmosphere of hydrogen, oxygen and nitrogen) using a rapid thermal processing system (which may be the rapid thermal processing system shown in FIG. 1A). In such a processing, oxidation or oxynitriding may be performed under a reduced pressure of about 1300 Pa.

In the first embodiment, the substrate 100 is not limited to any particular shape. For example, it may be formed in a disk shape.

The rapid thermal processing carried out using the rapid thermal processing system of the first embodiment may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like). In such a processing, the rapid thermal processing may be carried out under a reduced pressure of about 1300 Pa.

The heating unit 104 of the rapid thermal processing system in the first embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system in the first embodiment, one or more partitions transmitting light or the like from the heating lamp may be provided between the substrate 100 and the lamp. In such a case, the partition or partitions may be made of quartz or a material containing quartz.

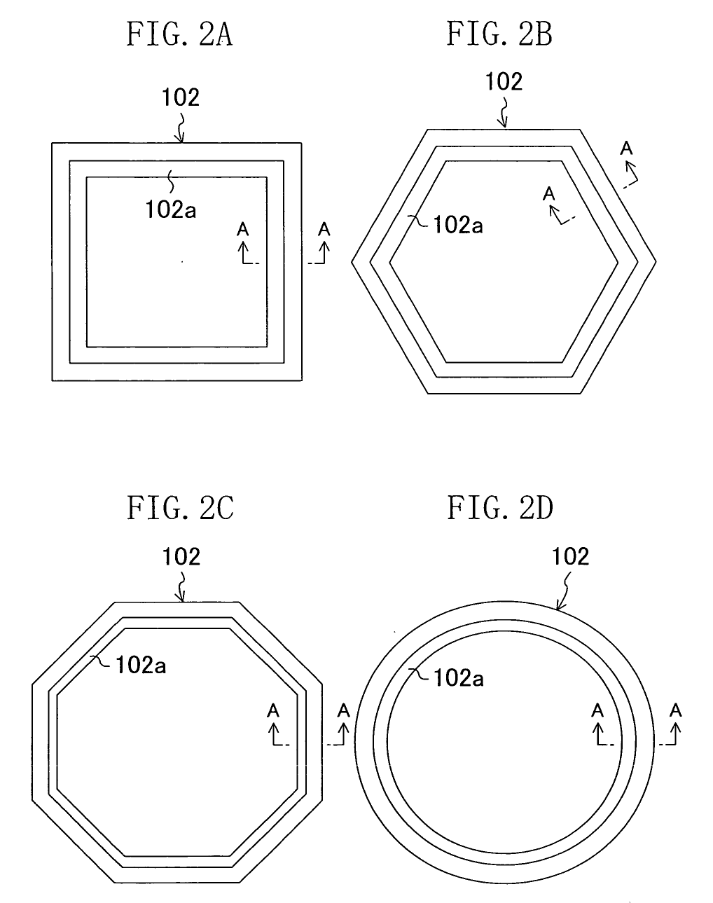

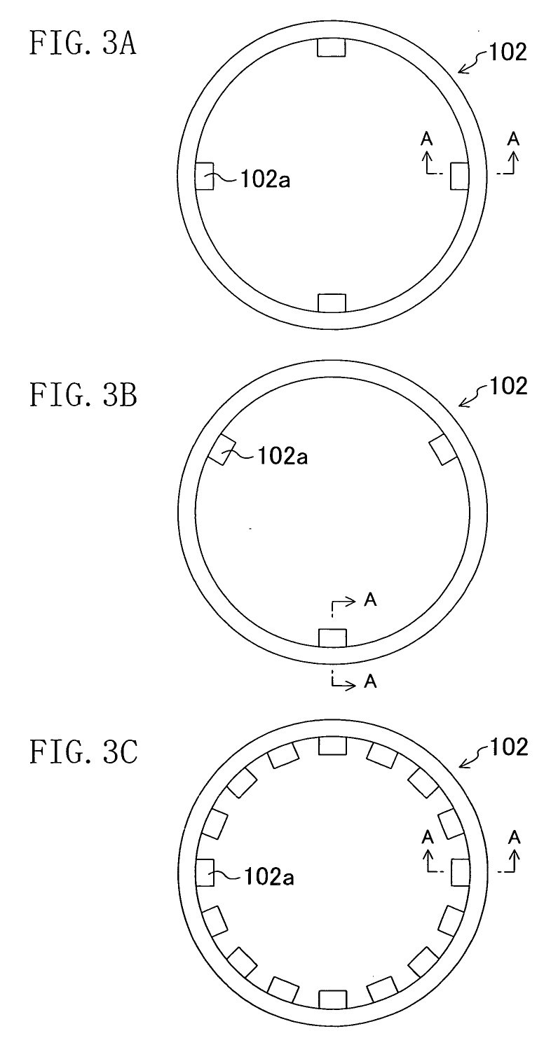

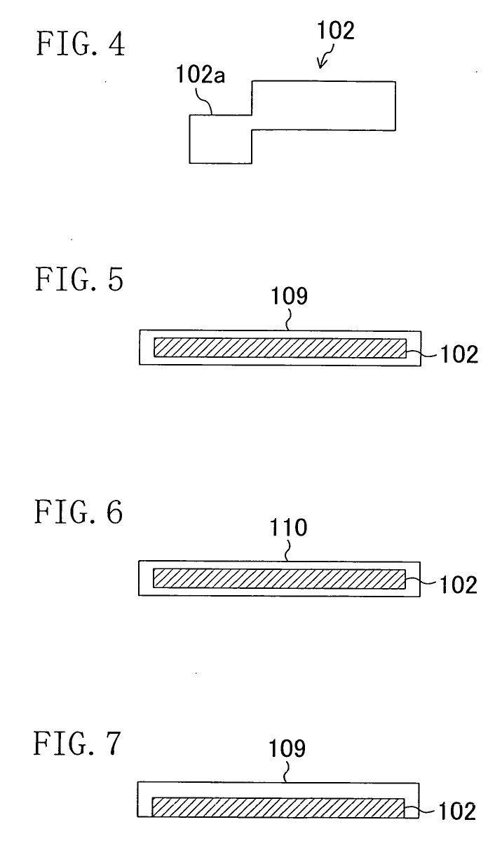

In the first embodiment, the plan shape of the substrate carrier 102 is not limited to any particular shape. For example, it may be annular. The substrate carrier 102 may be provided with a shelf for carrying the substrate 100. FIGS. 2A to 2D and FIGS. 3A to 3C show a variety of plan shapes of the substrate carriers 102 having shelves 102a, respectively. FIG. 4 shows a schematic sectional structure taken along the line A-A in each of FIGS. 2A to 2D and FIGS. 3A to 3C.

In the first embodiment, the substrate carrier 102 is disposed on the rotating unit 103. Alternatively, the substrate carrier 102 may be disposed on another driving mechanism.

In the first embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Second Embodiment

A rapid thermal processing system according to a second embodiment of the present invention will be described below with reference to the accompanying drawings.

The whole structure of the rapid thermal processing system according to the second embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In the second embodiment, at least one of the plurality of optical pyrometers 105 is placed around the edge of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the second embodiment is characterized in that in the rapid thermal processing system shown in FIG. 1A, the substrate carrier 102 has resistance to oxidation.

FIG. 5 is a view showing a sectional structure of the substrate carrier of the rapid thermal processing system according to the second embodiment.

To be more specific, the substrate carrier 102 of the second embodiment is mainly made of, for example, silicon. Silicon forming the surfaces of the substrate carrier 102 is nitrided to form strong Si—N bonds, whereby as shown in FIG. 5, the entire surfaces of the substrate carrier 102 are covered with a portion 109 having resistance to oxidation (nitrided portion 109).

By such a structure, even when oxidation processing or oxynitriding processing is carried out either at a relatively high temperature of 950° C. or more or in an atmosphere having a relatively strong ability of oxidization or oxynitriding, it becomes difficult to oxidize or oxynitride the substrate carrier 102 by such a processing. Therefore, a change in properties of the substrate carrier 102, in particular a change in emissivity becomes so small as to be negligible. As a result, an accurate measurement temperature invariable with time is transferred to the control system 106 while the optical pyrometer 105 provided around the edge of the substrate 100 never determines that the temperature of the substrate carrier 102 is changed with time. This prevents the thermal processing around the edge of the substrate 100 from changing with time. That is to say, the temperature controllability around the edge of the substrate 100 can be improved to suppress slips or the like in the substrate 100, which dramatically boosts yields of devices to be processed.

In the second embodiment, the entire surfaces of the substrate carrier 102 are covered with the nitrided portion 109. Alternatively, only the front surface of the substrate carrier 102, properly speaking, only the surface of the substrate carrier exposed to an atmosphere during the rapid thermal processing may be covered with the nitrided portion 109. In other words, the back surface of the substrate carrier 102, properly speaking, the surface of the substrate carrier 102 facing a space surrounded with the substrate 100, the substrate carrier 102, and the rotating unit 103 does not have to be covered with the nitrided portion 109.

In the second embodiment, the substrate 100 is not limited to any particular shape. For example, it may be formed in a disk shape.

The rapid thermal processing carried out using the rapid thermal processing system of the second embodiment may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like). In such a processing, the rapid thermal processing may be carried out under a reduced pressure of about 1300 Pa.

The heating unit 104 of the rapid thermal processing system in the second embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system in the second embodiment, one or more partitions transmitting light or the like from the heating lamp may be provided between the substrate 100 and the lamp. In such a case, the partition or partitions may be made of quartz or a material containing quartz.

In the second embodiment, the plan shape of the substrate carrier 102 is not limited to any particular shape. For example, it may be annular. The substrate carrier 102 may be provided with a shelf for carrying the substrate 100.

In the second embodiment, the substrate carrier 102 is disposed on the rotating unit 103. Alternatively, the substrate carrier 102 may be disposed on another driving mechanism.

In the second embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Third Embodiment

A rapid thermal processing system according to a third embodiment of the present invention will be described below with reference to the accompanying drawings.

The whole structure of the rapid thermal processing system according to the third embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In the third embodiment, at least one of the plurality of optical pyrometers 105 is placed around the edge of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the third embodiment is characterized in that in the rapid thermal processing system shown in FIG. 1A, the substrate carrier 102 has resistance to oxidation.

FIG. 6 is a view showing a sectional structure of the substrate carrier of the rapid thermal processing system according to the third embodiment.

To be more specific, in the third embodiment, the substrate 100 is a substrate whose main constituent element is silicon, such as a silicon wafer, and the substrate carrier 102 is mainly made of a material containing an element forming the substrate, that is, silicon (for example, SiC, polycrystalline silicon, or the like). In addition, by nitriding the surfaces of the substrate carrier 102, the entire surfaces of the substrate carrier 102 are covered with a portion 110 having resistance to oxidation (nitrided silicon portion 110) as shown in FIG. 6.

By such a structure, even when oxidation processing or oxynitriding processing is carried out either at a relatively high temperature of 950° C. or more or in an atmosphere having a relatively strong ability of oxidization or oxynitriding, it becomes difficult to oxidize or oxynitride the substrate carrier 102 by such a processing. Therefore, a change in properties of the substrate carrier 102, in particular a change in emissivity becomes so small as to be negligible. As a result, an accurate measurement temperature invariable with time is transferred to the control system 106 while the optical pyrometer 105 provided around the edge of the substrate 100 never determines that the temperature of the substrate carrier 102 is changed with time. This prevents the thermal processing around the edge of the substrate 100 from changing with time. That is to say, the temperature controllability around the edge of the substrate 100 can be improved to suppress slips or the like in the substrate 100, which dramatically boosts yields of devices to be processed.

In the third embodiment, the substrate 100 is not limited to any particular shape. For example, it may be formed in a disk shape.

The rapid thermal processing carried out using the rapid thermal processing system of the third embodiment may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like). In such a processing, the rapid thermal processing may be carried out under a reduced pressure of about 1300 Pa.

The heating unit 104 of the rapid thermal processing system in the third embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system in the third embodiment, one or more partitions transmitting light or the like from the heating lamp may be provided between the substrate 100 and the lamp. In such a case, the partition or partitions may be made of quartz or a material containing quartz.

In the third embodiment, the plan shape of the substrate carrier 102 is not limited to any particular shape. For example, it may be annular. The substrate carrier 102 may be provided with a shelf for carrying the substrate 100.

In the third embodiment, the substrate carrier 102 is disposed on the rotating unit 103. Alternatively, the substrate carrier 102 may be disposed on another driving mechanism.

In the third embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Fourth Embodiment

A rapid thermal processing system and a manufacturing method thereof according to a fourth embodiment of the present invention will be described below with reference to the accompanying drawings.

The whole structure of the rapid thermal processing system according to the fourth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In the fourth embodiment, at least one of the plurality of optical pyrometers 105 is placed around the edge of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the fourth embodiment is characterized in that in the substrate carrier 102 of the rapid thermal processing system shown in FIG. 1A, only a portion thereof exposed to an atmosphere during the rapid thermal processing has resistance to oxidation.

FIG. 7 is a view showing a sectional structure of the substrate carrier of the rapid thermal processing system according to the fourth embodiment.

To be more specific, the substrate carrier 102 of the fourth embodiment is mainly made of, for example, silicon. The surfaces of the substrate carrier 102 are nitrided by the rapid thermal processing system for use in the actual processing (the rapid thermal processing system in the fourth embodiment), or by another rapid thermal processing system equivalent to the system for use in the actual processing (in this case, the substrate carrier 102 is temporarily dismounted from the rapid thermal processing system of the fourth embodiment). By this nitriding, as shown in FIG. 7, only the portion of the substrate carrier 102 exposed to an atmosphere during the rapid thermal processing (properly speaking, the portion of the substrate carrier 102 which is expected to be changed with time by being exposed to an atmosphere of oxidation processing, oxynitriding processing, or other processings) is covered with a portion 109 having resistance to oxidation (nitrided portion 109).

By such a structure, even when oxidation processing or oxynitriding processing is carried out either at a relatively high temperature of 950° C. or more or in an atmosphere having a relatively strong ability of oxidization or oxynitriding, it becomes difficult to oxidize or oxynitride the portion of the substrate carrier 102 covered with the nitrided portion 109 (the portion of the substrate carrier 102 exposed to an atmosphere during the rapid thermal processing) by such a processing. Therefore, a change in properties of the substrate carrier 102, in particular a change in emissivity becomes so small as to be negligible. As a result, an accurate measurement temperature invariable with time is transferred to the control system 106 while the optical pyrometer 105 provided around the edge of the substrate 100 never determines that the temperature of the substrate carrier 102 is changed with time. This prevents the thermal processing around the edge of the substrate 100 from changing with time. That is to say, the temperature controllability around the edge of the substrate 100 can be improved to suppress slips or the like in the substrate 100, which dramatically boosts yields of devices to be processed.

Moreover, in the fourth embodiment, only the portion of the substrate carrier 102 exposed to an atmosphere during the rapid thermal processing has resistance to oxidation to provide the following effects.

To be more specific, since the portion of the substrate carrier 102 exposed to an atmosphere during the rapid thermal processing has the properties of the original material of the substrate carrier 102, the heat emissivity of the substrate carrier 102 is nearly invariable before and after impartation of oxidation resistance to the substrate carrier 102. Therefore, for example, even if the temperature condition (the setting condition or the like) of the rapid thermal processing system has been adjusted using the substrate carrier 102 before the impartation of oxidation resistance to the substrate carrier 102, the adjusted temperature condition can be put to use with very little adjustment. Also, the heat dissipation capability of the connecting portion between the substrate carrier 102 and the mechanism for supporting the carrier (specifically the rotating unit 103) is nearly invariable before and after impartation of oxidation resistance to the substrate carrier 102, so that the cooling efficiency of the rapid thermal processing system is kept in the original condition.

Furthermore, only the portion of the substrate carrier 102 exposed to an atmosphere during the rapid thermal processing has resistance to oxidation to provide the following effects. If, like the fourth embodiment, the mechanism for supporting the substrate carrier 102 is the rotating unit 103 and the substrate carrier 102 is in synchronization with the rotating unit 103, the contact portion between the substrate carrier 102 and the rotating unit 103 has to be kept at an appropriate friction coefficient. Specifically, in the case where this portion has an inappropriate friction coefficient, although the rotating unit 103 is rotating, the substrate carrier 102 slips on the rotating unit 103 and a normal rotation of the substrate carrier 102, that is, the substrate 100 cannot be accmplished. In addition to this, by the slipping, a mechanically polishing (rubbing action) arises at the contact point (the contact line) between the substrate carrier 102 and the rotating unit 103, and thus the contact point (the contact line) may become a source of particles or the like. As can be apparent from this, the friction coefficient of the portion of the substrate carrier 102 in contact with the rotating unit 103 (mechanism for supporting the substrate carrier) has to be large enough to have the ability to bear rotational inertia (centrifugal force), and generally the original substrate carrier 102 (the substrate carrier 102 without resistance to oxidation) is designed to meet this demand. On the other hands, if the oxidation resistance is imparted to this contact portion and the friction coefficient of this portion is changed, a newly caused trouble (occurrence of particles or the like) would occur even though the above problem can be solved. However, the region of the substrate carrier 102 containing the contact point (contact line) with the mechanism for supporting the substrate carrier 102 (the rotating unit 103) and not exposed to an atmosphere during rapid thermal processing (that is, the portion of the substrate carrier 102 not covered with the nitrided portion 109) does not have oxidation resistance imparted and is kept in the surface condition of the original substrate carrier 102, thereby solving the problems without causing any new troubles.

In the fourth embodiment, nitriding of the substrate carrier 102 using the rapid thermal processing system may be carried out in, for example, an atmosphere containing at least one of NH₃, NO, or N₂O. Specifically, a processing carried out, for example, in a NO atmosphere at about 1100° C. for several minutes to tens of minutes is carried out once or repeated several times to nitride the surface of the substrate carrier 102, whereby the oxidation resistance is imparted to the substrate carrier 102.

In the fourth embodiment, the substrate carrier 102 is nitrided using the rapid thermal processing system. Alternatively, even if the substrate carrier 102 is oxidized or oxynitrided using the rapid thermal processing system, oxidation resistance can be imparted to the substrate carrier 102 to provide the same effect as the fourth embodiment.

In the fourth embodiment, the substrate 100 is not limited to any particular shape. For example, it may be formed in a disk shape.

The rapid thermal processing carried out using the rapid thermal processing system of the fourth embodiment may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like). In such a processing, the rapid thermal processing may be carried out under a reduced pressure of about 1300 Pa.

The heating unit 104 of the rapid thermal processing system in the fourth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system in the fourth embodiment, one or more partitions transmitting light or the like from the heating lamp may be provided between the substrate 100 and the lamp. In such a case, the partition or partitions may be made of quartz or a material containing quartz.

In the fourth embodiment, the plan shape of the substrate carrier 102 is not limited to any particular shape. For example, it may be annular. The substrate carrier 102 may be provided with a shelf for carrying the substrate 100.

In the fourth embodiment, the substrate carrier 102 is disposed on the rotating unit 103. Alternatively, the substrate carrier 102 may be disposed on another driving mechanism.

In the fourth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Fifth Embodiment

A temperature adjustment method according to a fifth embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the fifth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the fifth embodiment is characterized in that the rapid thermal processing system shown in FIG. 1A, the substrate 100 is subjected to rapid thermal processing to acquire the quantity of temperature dependence (referred hereinafter to as the temperature dependence quantity) and subsequently temperature shifts of the individual optical pyrometers 105 are independently corrected based on the temperature dependence quantity. Hereinafter, the characteristic of the fifth embodiment will be described in detail with reference to the accompanying drawings.

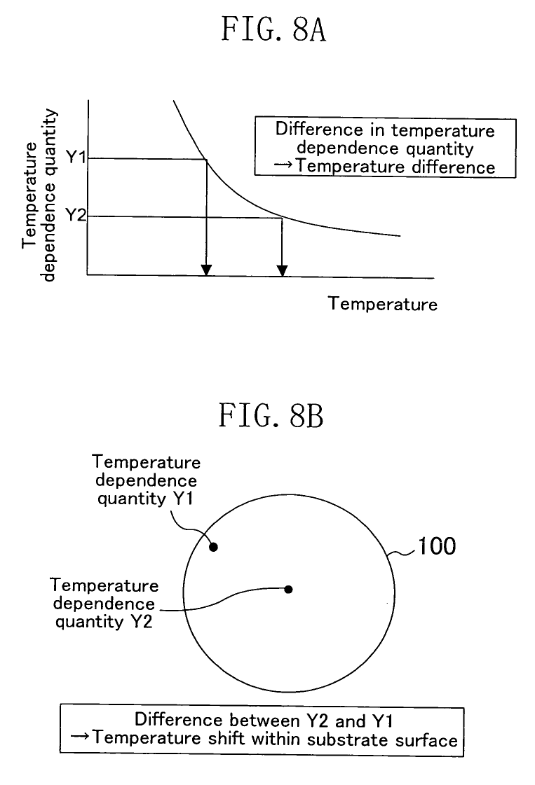

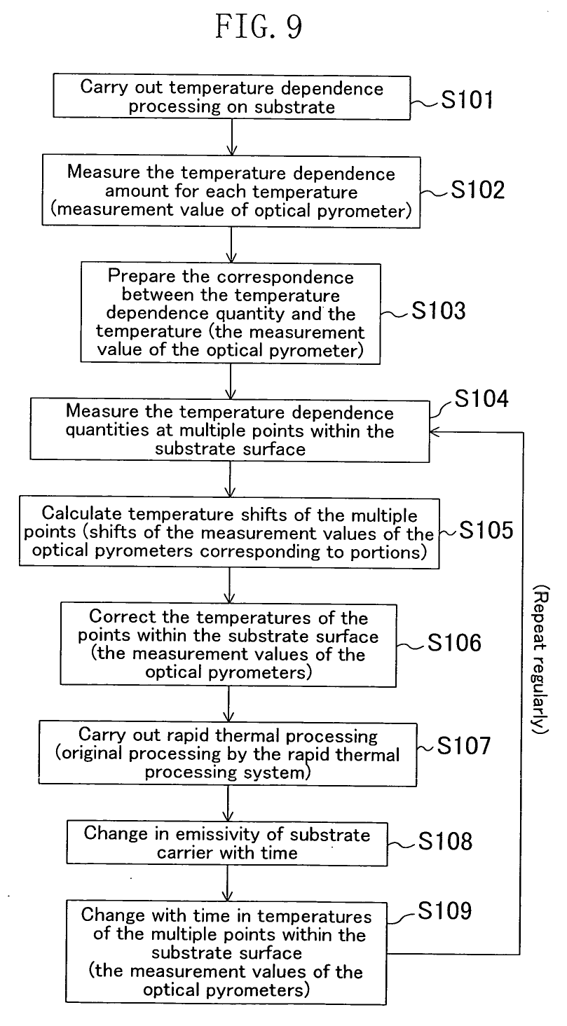

FIGS. 8A and 8B are a graph and a view for describing the characteristic of the fifth embodiment, respectively, and FIG. 9 is a flowchart of the temperature adjustment method of the fifth embodiment.

To be more specific, first, in the step S101, temperature dependence processing (rapid thermal processing) is carried out on the substrate 100, and in the step S102, the physical quantity of the substrate 100 thus varying depending on the processing temperature of the rapid thermal processing, that is, the temperature dependence quantity is measured for each of the temperatures (each measurement value of the optical pyrometer 105). The temperature dependence quantity may be sheet resistance. Alternatively, the amount of phase change of a metal film deposited on the substrate 100 relative to the processing temperature (for example, the temperature of phase transition) or the like may be utilized as the temperature dependence quantity.

In the measurement of the temperature dependence quantity, the temperature dependence quantity obtained by measuring a certain point designated within the surface of the substrate 100 may be associated with the measurement temperature of the optical pyrometer 105 corresponding to that point and a portion of the heating unit 104 contributing to the thermal processing of that point. Alternatively, the average of the physical quantities measured at multiple points within the surface of the substrate 100 may be calculated to associate the calculated average with the average of the measurement temperatures of all the optical pyrometers 105 corresponding to the multiple points and all portions of the heating unit 104 contributing to thermal processing of the multiple points.

Next, in the step S103, the correspondence between the temperature dependence quantity (the physical quantity of the substrate 100) and the temperature (the measurement value of the optical pyrometers 105) is prepared based on the temperature dependence quantity measured in the step S102.

The temperature dependence quantity is uniquely determined by the temperature. Therefore, as shown in FIGS. 8A and 8B, if there are differences among the temperature dependence quantities within the surface of the substrate 100, the differences correspond to temperature shifts (temperature differences). In the fifth embodiment, utilizing the relation between the difference in the temperature dependence quantity and the temperature shift, the measurement temperatures of the optical pyrometers 105 are corrected so that the temperature dependence quantity has a value associated with a desired temperature.

To be more specific, in the step S104, the temperature dependence quantities are measured at multiple points within the surface of the substrate 100 during the rapid thermal processing. Next, in the step S105, based on the differences among the temperature dependence quantities measured at the multiple points and the correspondence prepared in the step S103 (the correspondence between the temperature dependence quantity and the temperature), temperature shifts of the multiple points (shifts of the measurement values of the optical pyrometers 105) are calculated. Then, in the step S106, the temperatures of the multiple points within the surface of the substrate 100 (the measurement values of the optical pyrometers 105) are corrected based on the temperature shifts calculated in the step S105. In this correction, the temperature shifts of the individual optical pyrometers 105 are independently corrected. Thereafter, in the step S107, rapid thermal processing (the original rapid thermal processing by the rapid thermal processing system shown in FIG. 1A) is carried out on the substrate 100. During this processing, in the step S108, properties of the substrate carrier 102 (in particular the emissivity) are changed with time, so that in the step S109, the temperatures of the multiple points within the surface of the substrate 100 (the measurement values of the optical pyrometers 105) are also changed with time. To deal with this change, in the fifth embodiment, a sequence of the steps S104 to S109 is regularly carried out, whereby temperature shifts are calculated based on differences among the temperature dependence quantities corresponding to the portions within the surface of the substrate 100 to make temperature corrections. By this procedure, a change with time in the temperature shift of the optical pyrometer 105 disposed around the edge of the substrate 100 can be prevented which results from the change with time in the emissivity or the like of the substrate carrier 102.

As described above, in the fifth embodiment, the substrate 100 is subjected to rapid thermal processing to acquire the temperature dependence quantity, and then temperature shifts of the individual optical pyrometers 105 are independently corrected based on the acquired temperature dependence quantity. That is to say, utilizing the fact that the difference in the temperature dependence quantity within the surface of the substrate 100 corresponds to the temperature shift, the measurement temperatures of the optical pyrometers 105 can be corrected so that the temperature dependence quantity has a value corresponding to a desired temperature. Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the fifth embodiment, the steps S101 and S104 may be carried out using a dummy substrate equivalent to the substrate 100.

Temperature correction in the fifth embodiment may be made either to only the optical pyrometers 105 disposed around the edge of the substrate 100, or to a predetermined number or all of the optical pyrometers 105.

In the fifth embodiment, the substrate 100 is not limited to any particular shape. For example, it may be formed in a disk shape.

In the fifth embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the fifth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the fifth embodiment, one or more partitions transmitting light or the like from the heating lamp may be provided between the substrate 100 and the lamp. In such a case, the partition or partitions may be made of quartz or a material containing quartz.

In the rapid thermal processing system used in the fifth embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the fifth embodiment, the substrate carrier 102 is disposed on the rotating unit 103. Alternatively, the substrate carrier 102 may be disposed on another driving mechanism.

In the fifth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Sixth Embodiment

A temperature adjustment method according to a sixth embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the sixth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the sixth embodiment is characterized in that in the rapid thermal processing system shown in FIG. 1A, the substrate 100 is subjected to rapid thermal processing to measure the temperature dependence quantity (the physical quantity of the substrate 100 varying depending on the processing temperature of the rapid thermal processing), specifically the amount of slips occurring in the substrate 100, and subsequently temperature shifts of the individual optical pyrometers 105 are independently corrected based on the amount of occurring slips. In this embodiment, as the amount of occurring slips, the number of slips with a length of several millimeters or greater or the number of all recognizable slips may be used. Alternatively, for example, the length of the longest slip occurring may be used. In the sixth embodiment, as the index of the temperature of the rapid thermal processing, the amount of temperature correction (the temperature correction amount ΔT) is employed for correcting a temperature shift of the optical pyrometer 105 disposed around the edge of the substrate 100. Hereinafter, the characteristic of the sixth embodiment will be described in detail with reference to the accompanying drawings.

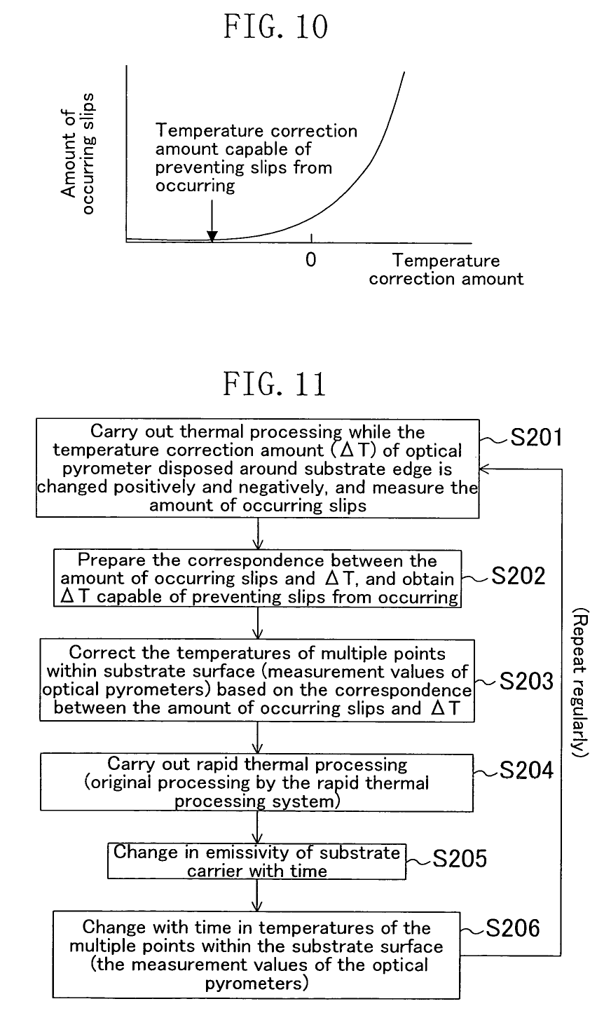

FIG. 10 shows the amount of slips occurring as the temperature correction amount ΔT is changed. As shown in FIG. 10, as the temperature correction amount ΔT is increased in the positive direction (as the measurement value of the optical pyrometer 105 disposed around the edge of the substrate 100 is corrected to a higher value), the amount of occurring slips sharply rises. Conversely, even if the temperature correction amount ΔT is increased in the negative direction (even if the measurement value of the optical pyrometer 105 disposed around the edge of the substrate 100 is corrected to a lower value), no slip occurs. In the sixth embodiment, the temperature correction amount ΔT capable of preventing slips from occurring is obtained based on the relation shown in FIG. 10 between the temperature correction amount ΔT and the amount of occurring slips, and the temperature (the measurement value) of the optical pyrometer 105 disposed around the edge of the substrate 100 is corrected using the obtained temperature correction amount ΔT. That is to say, in the sixth embodiment, it is conceivable that by the temperature correction amount ΔT capable of preventing slips from occurring, temperature shifts within the surface of the substrate 100 caused by the rapid thermal processing are made uniform.

FIG. 11 is a flowchart of the temperature adjustment method according to the sixth embodiment.

First, in the step S201, the substrate 100 is subjected to thermal processing while the temperature correction amount ΔT of the optical pyrometer 105 disposed around the edge of the substrate 100 is changed in the positive and negative directions. This processing creates a temperature difference between the vicinity of the edge and the center portion of the substrate 100, so that slips occur within the substrate 100. Then, the amount of occurring slips within the substrate 100 is measured as the temperature dependence quantity.

Next, in the step S202, the correspondence between the amount of occurring slips measured in the step S201 and the temperature correction amount ΔT is prepared. Based on the prepared correspondence, the temperature correction amount ΔT capable of preventing slips from occurring is obtained.

Then, in the step S203, the temperatures of the multiple points within the surface of the substrate 100 (the measurement values of the optical pyrometers 105) are corrected using the temperature correction amount ΔT which can prevent slips from occurring and which is obtained in the step S202. That is to say, based on the correspondence between the amount of occurring slips and the temperature correction amount ΔT, temperature shifts of the individual optical pyrometers 105 are independently corrected.

Thereafter, in the step S204, rapid thermal processing (the original rapid thermal processing by the rapid thermal processing system shown in FIG. 1A) is carried out on the substrate 100. During this processing, in the step S205, properties of the substrate carrier 102 (in particular the emissivity) are changed with time, so that in the step S206, the temperatures of the multiple points within the surface of the substrate 100 (the measurement values of the optical pyrometers 105) are also changed with time. To deal with this change, in the sixth embodiment, a sequence of the steps S201 to S206 is regularly carried out to measure the amount of slips occurring within the substrate 100 which corresponds to the temperature correction amount ΔT. The temperature correction amount ΔT obtained by the measurement result and capable of preventing slips from occurring is used to make temperature corrections. By this procedure, a change with time in the temperature shift of the optical pyrometer 105 disposed around the edge of the substrate 100 can be prevented which results from the change with time in the emissivity or the like of the substrate carrier 102.

As described above, in the sixth embodiment, the substrate 100 is subjected to rapid thermal processing to acquire the amount of slips occurring within the substrate 100, and then temperature shifts of the optical pyrometers 105 are independently corrected based on the amount of occurring slips. That is to say, the amount of slips occurring within the substrate 100 which corresponds to the temperature correction amount ΔT is measured, and using the temperature correction amount ΔT obtained by the measurement result and capable of preventing slips from occurring, the measurement temperatures of the optical pyrometers 105 can be corrected. Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the sixth embodiment, the step S201 may be carried out using a dummy substrate equivalent to the substrate 100.

Temperature correction in the sixth embodiment may be made either to only the optical pyrometers 105 disposed around the edge of the substrate 100, or to a predetermined number or all of the optical pyrometers 105.

In the sixth embodiment, the substrate 100 is not limited to any particular shape. For example, it may be formed in a disk shape.

In the sixth embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the sixth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the sixth embodiment, one or more partitions transmitting light or the like from the heating lamp may be provided between the substrate 100 and the lamp. In such a case, the partition or partitions may be made of quartz or a material containing quartz.

In the rapid thermal processing system used in the sixth embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the sixth embodiment, the substrate carrier 102 is disposed on the rotating unit 103. Alternatively, the substrate carrier 102 may be disposed on another driving mechanism.

In the sixth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Seventh Embodiment

A temperature adjustment method according to a seventh embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the seventh embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the seventh embodiment is characterized in that in the rapid thermal processing system shown in FIG. 1A, the substrate 100 is subjected to rapid thermal processing to measure the temperature dependence quantity (the physical quantity of the substrate 100 varying depending on the processing temperature of the rapid thermal processing), specifically the thickness of an oxide film formed on the substrate 100 by oxidation and subsequently temperature shifts of the individual optical pyrometers 105 are independently corrected based on the measured thickness of the oxide film. Herein, if the substrate 100 is made of, for example, silicon, the thickness of the oxide film described above is the thickness of a film formed by thermally oxidizing silicon (a SiO₂ film). Hereinafter, the characteristic of the seventh embodiment will be described in detail with reference to the accompanying drawings.

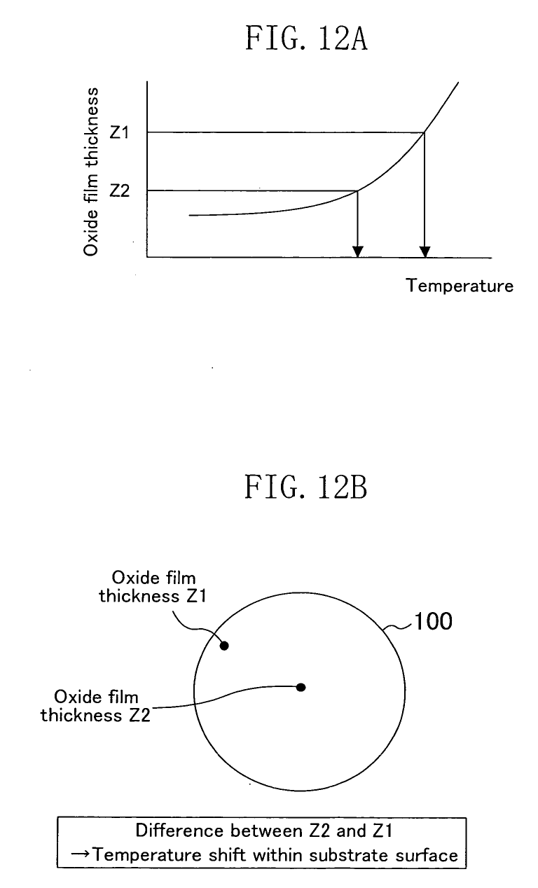

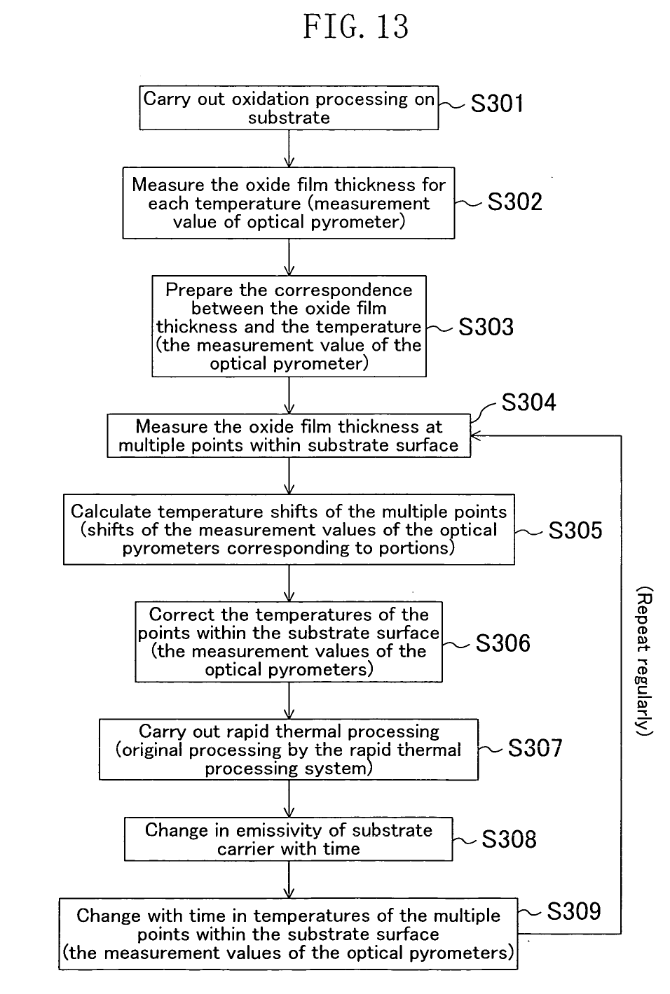

FIGS. 12A and 12B are a graph and a view for describing the characteristic of the seventh embodiment, respectively, and FIG. 13 is a flowchart of the temperature adjustment method of the seventh embodiment.

To be more specific, first, in the step S301, oxidation processing (rapid thermal processing) is carried out on the substrate 100, and in the step S302, the thickness of a formed oxide film is measured for each of the temperatures (the measurement value of the optical pyrometer 105). In the step S301, the oxidation processing may be carried out, for example, at about 1000° C. for about tens of seconds to several minutes.

Next, in the step S303, the correspondence between the thickness of the oxide film and the temperature (the measurement value of the optical pyrometers 105) is prepared based on the thickness of the oxide film measured in the step S302.

The thickness of the oxide film is uniquely determined by the temperature. Therefore, as shown in FIGS. 12A and 12B, if there is a difference in the thickness of the oxide film within the surface of the substrate 100, the difference corresponds to temperature shift (temperature difference). In the seventh embodiment, utilizing the relation between the difference in the thickness of the oxide film and the temperature shift, the measurement temperatures of the optical pyrometers 105 are corrected so that the thickness of the oxide film has a value associated with a desired temperature.

To be more specific, in the step S304, the thicknesses of portions of the oxide film are measured at multiple points within the surface of the substrate 100 during the rapid thermal processing. Next, in the step S305, based on differences among the thicknesses of portions of the oxide film measured at the multiple points and the correspondence prepared in the step S303 (the correspondence between the thickness of the oxide film and the temperature), temperature shifts of the multiple points (shifts of the measurement values of the optical pyrometers 105 associated with the multiple points) are calculated. Then, in the step S306, the temperatures of the multiple points within the surface of the substrate 100 (the measurement values of the optical pyrometers 105) are corrected based on the temperature shifts calculated in the step S305. In this correction, the temperature shifts of the individual optical pyrometers 105 are independently corrected. Thereafter, in the step S307, rapid thermal processing (the original rapid thermal processing by the rapid thermal processing system shown in FIG. 1A) is carried out on the substrate 100. During this processing, in the step S308, properties of the substrate carrier 102 (in particular the emissivity) are changed with time, so that in the step S309, the temperatures of the multiple points within the surface of the substrate 100 (the measurement values of the optical pyrometers 105) are also changed with time. To deal with this change, in the seventh embodiment, a sequence of the steps S304 to S309 is regularly carried out, whereby temperature shifts are calculated based on differences among the thicknesses of portions of the oxide film corresponding to the portions within the surface of the substrate 100, thereby making temperature corrections. By this procedure, a change with time in the temperature shift of the optical pyrometer 105 disposed around the edge of the substrate 100 can be prevented which results from the change with time in the emissivity or the like of the substrate carrier 102.

As described above, in the seventh embodiment, the substrate 100 is subjected to rapid thermal processing to acquire the thickness of the oxide film, and then temperature shifts of the optical pyrometers 105 are independently corrected based on the acquired thickness of the oxide film. That is to say, utilizing the fact that the difference in the thickness of the oxide film within the surface of the substrate 100 corresponds to the temperature shift, the measurement temperatures of the optical pyrometers 105 can be corrected so that the thickness of the oxide film has a value corresponding to a desired temperature. Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the seventh embodiment, the steps S301 and S304 may be carried out using a dummy substrate equivalent to the substrate 100.

Temperature correction in the seventh embodiment may be made either to only the optical pyrometers 105 disposed around the edge of the substrate 100, or to a predetermined number or all of the optical pyrometers 105.

In the seventh embodiment, the substrate 100 is not limited to any particular shape. For example, it may be formed in a disk shape.

In the seventh embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the seventh embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the seventh embodiment, one or more partitions transmitting light or the like from the heating lamp may be provided between the substrate 100 and the lamp. In such a case, the partition or partitions may be made of quartz or a material containing quartz.

In the rapid thermal processing system used in the seventh embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the seventh embodiment, the substrate carrier 102 is disposed on the rotating unit 103. Alternatively, the substrate carrier 102 may be disposed on another driving mechanism.

In the seventh embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Eighth Embodiment

A temperature adjustment method according to an eighth embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the eighth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the eighth embodiment is characterized in that in the rapid thermal processing system shown in FIG. 1A, the substrate 100 is subjected to rapid thermal processing to measure the temperature dependence quantity (the physical quantity of the substrate 100 varying depending on the processing temperature of the rapid thermal processing), specifically the thickness of an oxide film formed on the substrate 100 by oxidation and subsequently temperature shifts of the individual optical pyrometers 105 are independently corrected based on the measured thickness of the oxide film. Herein, if the substrate 100 is made of, for example, silicon, the thickness of the oxide film described above is the thickness of a film formed by thermally oxidizing silicon (a SiO₂ film). Hereinafter, the characteristic of the eighth embodiment will be described in detail with reference to the accompanying drawings.

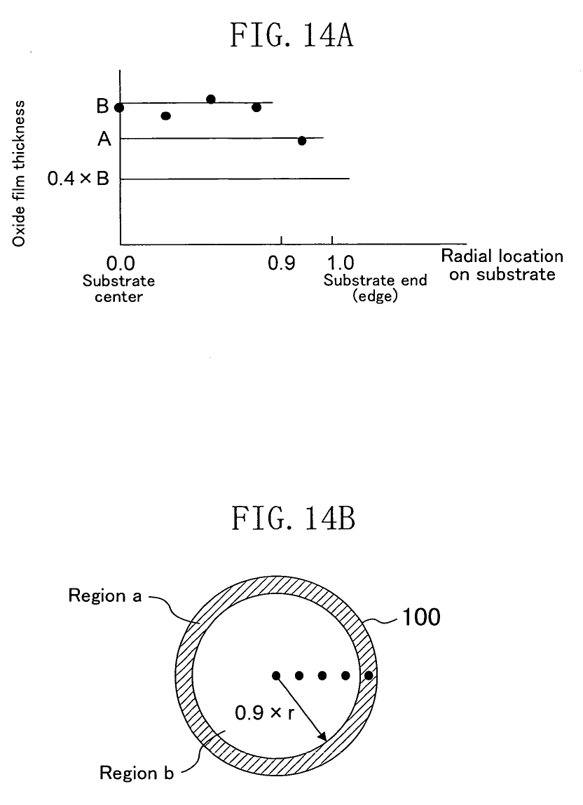

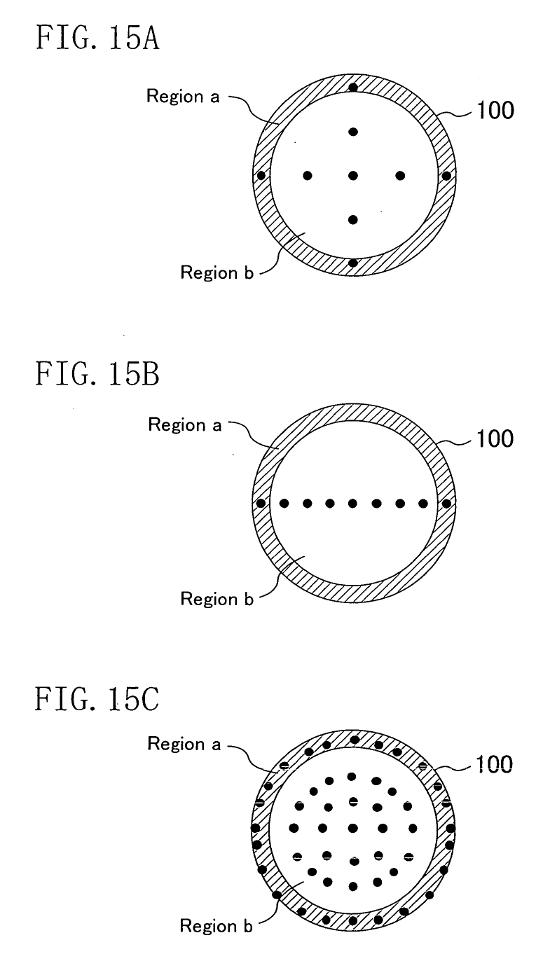

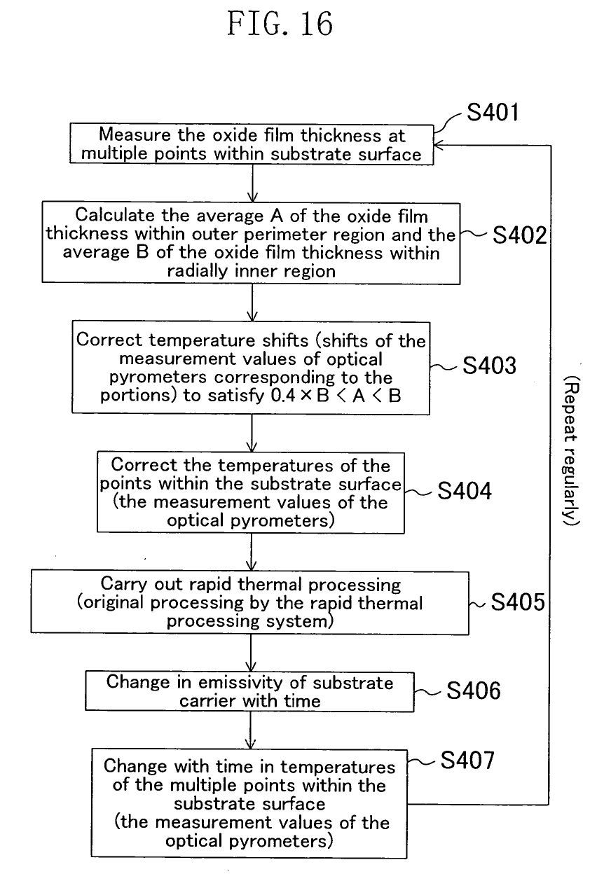

FIGS. 14A, 14B, and 15A to 15C are a graph and a view for describing the characteristic of the eighth embodiment, and FIG. 16 is a flowchart of the temperature adjustment method of the eighth embodiment.

To be more specific, first, in the step S401, the thicknesses of portions of the oxide film are measured at multiple points within the surface of the substrate 100 during the rapid thermal processing.

Next, in the step S402, calculation is made of the average A of the thicknesses of portions of the oxide film measured at multiple arbitrary points located within the outer perimeter region (region a) of the substrate 100 with a width of 10% of the radius (r) of the substrate 100, and of the average B of the thicknesses of portions of the oxide film measured at multiple arbitrary points within a region (region b) of the substrate 100 located radially inwardly from the outer perimeter region (see FIG. 14B). Measurement of the thicknesses of the portions of the oxide film may be made, for example, in such a manner that: as shown in FIG. 15A, of nine points arranged on the main surface of the substrate 100 in a cross arrangement (four points in the region a, and five points in the region b), the average of the measurement values of the four points in the region a is defined as A and the average of the measurement values of the five points in the region b is defined as B; as shown in FIG. 15B, of nine points diametrically arranged on the main surface of the substrate 100 (two points in the region a, and seven points in the region b), the average of the measurement values of the two points in the region a is defined as A and the average of the measurement values of the seven points in the region b is defined as B; or as shown in FIG. 15C, of 49 points concentrically arranged on the main surface of the substrate 100 (24 points in the region a, and 25 points in the region b), the average of the measurement values of the 24 points in the region a is defined as A and the average of the measurement values of the 25 points in the region b is defined as B.

Next, in the step S403, comparison is made between A and B obtained in the step S402, and then temperature shifts (shifts of the measurement values of the optical pyrometers 105) are corrected to satisfy 0.4×B<A<B (see FIG. 14A: Note that, for simplification, the measurement point in the region a is one point in FIGS. 14A and 14B). Specifically, for example, if B is smaller than A, correction of the temperature shift capable of making B larger than A is made to the optical pyrometer 105 that will affect B. Alternatively, correction of the temperature shift capable of making A smaller than B and larger than 0.4×B may be made to the optical pyrometer 105 that will affect A. Thus, in the step S404, the temperatures of the multiple points within the surface of the substrate 100 (the measurement values of the optical pyrometers 105) are corrected. Note that the temperature shifts of the optical pyrometers 105 are independently corrected.

Thereafter, in the step S405, rapid thermal processing (the original rapid thermal processing by the rapid thermal processing system shown in FIG. 1A) is carried out on the substrate 100. During this processing, in the step S406, properties of the substrate carrier 102 (in particular the emissivity) are changed with time, so that in the step S407, the temperatures of the multiple points within the surface of the substrate 100 (the measurement values of the optical pyrometers 105) are also changed with time. To deal with this change, in the eighth embodiment, a sequence of the steps S401 to S407 is regularly carried out, whereby temperature correction is carried out on the optical pyrometers 105. By this procedure, a change with time in the temperature shift of the optical pyrometer 105 disposed around the edge of the substrate 100 can be prevented which results from the change with time in the emissivity or the like of the substrate carrier 102.

As described above, in the eighth embodiment, the substrate 100 is subjected to rapid thermal processing to acquire the thickness of the oxide film, and then temperature shifts of the optical pyrometers 105 are independently corrected based on the acquired thickness of the oxide film. To be more specific, temperature shifts (shifts of the measurement values of the optical pyrometers 105) are corrected to satisfy 0.4×B<A<B (where A is the average of the thicknesses of portions of the oxide film measured at multiple arbitrary points located within the outer perimeter region of the substrate 100 with a width of 10% of the radius (r) of the substrate 100, and B is the average of the thicknesses of portions of the oxide film measured at multiple arbitrary points of a region of the substrate 100 located radially inwardly from the outer perimeter region). Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the eighth embodiment, the step S401 may be carried out using a dummy substrate equivalent to the substrate 100.

Temperature correction in the eighth embodiment may be made either to only the optical pyrometers 105 disposed around the edge of the substrate 100, or to a predetermined number or all of the optical pyrometers 105.

In the eighth embodiment, the boundary between the outer perimeter region (the region a) of the substrate 100 targeted for calculation of the average A of the thickness of the oxide film and the region (the region b) radially inside the substrate 100 targeted for calculation of the average B of the thickness of the oxide film is set at a location radially inwardly from the edge of the substrate 100 by 10% of the radius (r) of the substrate 100. However, the location of the boundary is not limited to any particular position.

In the eighth embodiment, temperature shifts are corrected to satisfy 0.4×B<A<B. In this correction, the lower limit of A (0.4×B in this embodiment) is not limited to any particular value as long as A is smaller than B.

In the eighth embodiment, the substrate 100 is not limited to any particular shape. For example, it may be formed in a disk shape.

In the eighth embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the eighth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the eighth embodiment, one or more partitions transmitting light or the like from the heating lamp may be provided between the substrate 100 and the lamp. In such a case, the partition or partitions may be made of quartz or a material containing quartz.

In the rapid thermal processing system used in the eighth embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the eighth embodiment, the substrate carrier 102 is disposed on the rotating unit 103. Alternatively, the substrate carrier 102 may be disposed on another driving mechanism.

In the eighth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Ninth Embodiment

A temperature adjustment method according to a ninth embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the ninth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the ninth embodiment is characterized in that in the rapid thermal processing system shown in FIG. 1A, the substrate 100 is subjected to rapid thermal processing to measure the temperature dependence quantity (the physical quantity of the substrate 100 varying depending on the processing temperature of the rapid thermal processing), specifically the amount of slips occurring in the substrate 100, and subsequently temperature shifts of the individual optical pyrometers 105 are independently corrected based on the amount of occurring slips. In this embodiment, as the amount of occurring slips, the number of slips with a length of several millimeters or greater or the number of all recognizable slips may be used. Alternatively, for example, the length of the longest slip occurring may be used. In the ninth embodiment, as the index of the temperature of the rapid thermal processing, the amount of temperature correction (the temperature correction amount ΔT) is employed for correcting temperature shift of the optical pyrometer 105 disposed around the edge of the substrate 100. Hereinafter, the characteristic of the ninth embodiment will be described in detail with reference to the accompanying drawings.

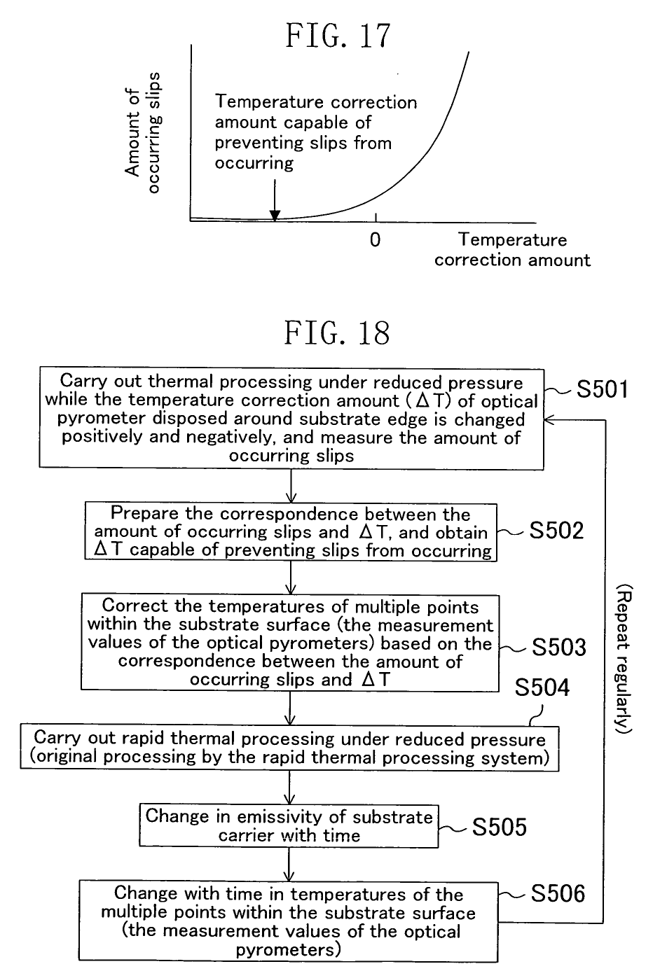

FIG. 17 shows the amount of slips occurring as the temperature correction amount ΔT is changed. As shown in FIG. 17, as the temperature correction amount ΔT is increased in the positive direction (as the measurement value of the optical pyrometer 105 disposed around the edge of the substrate 100 is corrected to a higher value), the amount of occurring slips sharply rises. Conversely, even if the temperature correction amount ΔT is increased in the negative direction (even if the measurement value of the optical pyrometer 105 disposed around the edge of the substrate 100 is corrected to a lower value), no slip occurs. In the ninth embodiment, the temperature correction amount ΔT capable of preventing slips from occurring is obtained based on the relation shown in FIG. 17 between the temperature correction amount ΔT and the amount of occurring slips, and the temperature (the measurement value) of the optical pyrometer 105 disposed around the edge of the substrate 100 is corrected using the obtained temperature correction amount ΔT. That is to say, in the ninth embodiment, it is conceivable that by the temperature correction amount ΔT capable of preventing slips from occurring, temperature shifts within the surface of the substrate 100 caused by the rapid thermal processing is made uniform.

FIG. 18 is a flowchart of the temperature adjustment method according to the ninth embodiment.

First, in the step S501, the substrate 100 is subjected to thermal processing while the temperature correction amount ΔT of the optical pyrometer 105 disposed around the edge of the substrate 100 is changed in the positive and negative directions. This processing creates a temperature difference between the vicinity of the edge and the center portion of the substrate 100, so that slips occur within the substrate 100. Then, the amount of occurring slips within the substrate 100 is measured as the temperature dependence quantity. In the ninth embodiment, the rapid thermal processing for measuring the amount of occurring slips is carried out under a reduced pressure (for example, about 1300 Pa). This provides the following effects. Since, in the case of the processing under a reduced pressure, its cooling efficiency after the rapid thermal processing is poorer than the processing under an atmospheric pressure, the heat dissipation efficiencies of the substrate 100 and the substrate carrier 102 are significantly lowered. As a result, the substrate carrier 102 having insufficiently been cooled is used for the processing of the next substrate 100, so that the temperature difference between the substrate carrier 102 and the edge of the substrate 100 tends to be large to cause the problem that slips occur easily. On the other hands, in the ninth embodiment, acquirement of the temperature dependence quantity for correcting temperature shifts is carried out under a reduced pressure identical to the actual processing, whereby the accuracy of the temperature correction can be dramatically improved to prevent the above problem, that is, the occurrence of slips.

Next, in the step S502, the correspondence between the amount of occurring slips measured in the step S501 and the temperature correction amount ΔT is prepared. Based on the prepared correspondence, the temperature correction amount ΔT capable of preventing slips from occurring is obtained.

Then, in the step S503, the temperatures of the multiple points within the surface of the substrate 100 (the measurement values of the optical pyrometers 105) are corrected using the temperature correction amount ΔT which can prevent slips from occurring and which is obtained in the step S502. That is to say, based on the correspondence between the amount of occurring slips and the temperature correction amount ΔT, temperature shifts of the individual optical pyrometers 105 are independently corrected.

Thereafter, in the step S504, rapid thermal processing (the original rapid thermal processing by the rapid thermal processing system shown in FIG. 1A) is carried out on the substrate 100 under a reduced pressure. During this processing, in the step S505, properties of the substrate carrier 102 (in particular the emissivity) are changed with time, so that in the step S506, the temperatures of the multiple points within the surface of the substrate 100 (the measurement values of the optical pyrometers 105) are also changed with time. To deal with this change, in the ninth embodiment, a sequence of the steps S501 to S506 is regularly carried out to measure the amount of slips occurring within the substrate 100 which corresponds to the temperature correction amount ΔT. The temperature correction amount ΔT obtained by the measurement result and capable of preventing slips from occurring is used to make temperature corrections. By this procedure, a change with time in the temperature shift of the optical pyrometer 105 disposed around the edge of the substrate 100 can be prevented which results from the change with time in the emissivity or the like of the substrate carrier 102.

As described above, in the ninth embodiment, the substrate 100 is subjected to rapid thermal processing to acquire the amount of slips occurring within the substrate 100, and then temperature shifts of the optical pyrometers 105 are independently corrected based on the amount of occurring slips. That is to say, the amount of slips occurring within the substrate 100 which corresponds to the temperature correction amount ΔT is measured, and using the temperature correction amount ΔT obtained by the measurement result and capable of preventing slips from occurring, the measurement temperatures of the optical pyrometers 105 can be corrected. Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the ninth embodiment, since the rapid thermal processing for measuring the amount of occurring slips as the temperature dependence quantity is carried out under a reduced pressure, the accuracy of the temperature correction can be dramatically improved to more successfully prevent the occurrence of slips or other troubles.

In the ninth embodiment, the step S501 may be carried out using a dummy substrate equivalent to the substrate 100.

Temperature correction in the ninth embodiment may be made either to only the optical pyrometers 105 disposed around the edge of the substrate 100, or to a predetermined number or all of the optical pyrometers 105.

In the ninth embodiment, the substrate 100 is not limited to any particular shape. For example, it may be formed in a disk shape.

In the ninth embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the ninth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the ninth embodiment, one or more partitions transmitting light or the like from the heating lamp may be provided between the substrate 100 and the lamp. In such a case, the partition or partitions may be made of quartz or a material containing quartz.

In the rapid thermal processing system used in the ninth embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the ninth embodiment, the substrate carrier 102 is disposed on the rotating unit 103. Alternatively, the substrate carrier 102 may be disposed on another driving mechanism.

In the ninth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

### Tenth Embodiment

A temperature adjustment method according to a tenth embodiment of the present invention, specifically a temperature adjustment method for adjusting the temperature of a substrate in a rapid thermal processing system by which rapid thermal processing of the substrate is carried out will be described below with reference to the accompanying drawings.

The whole structure of the rapid thermal processing system for carrying out the temperature adjustment method according to the tenth embodiment is similar to that of the first embodiment shown in FIG. 1A. To be more specific, in a process chamber 101 of the rapid thermal processing system shown in FIG. 1A, the end (edge) of a substrate 100 to be processed is carried by an annular substrate carrier 102. The substrate carrier 102 is placed in the bottom portion within the process chamber 101 with a rotating unit 103 interposed therebetween. The upper portion of the process chamber 101 is provided with a heating unit 104, and an area within the process chamber 101 located under the substrate 100 is provided with a plurality of optical pyrometers 105 so that the optical pyrometers 105 are not in direct contact with the substrate 100. The heating unit 104 and the optical pyrometers 105 are controlled by a control system 106 provided outside the process chamber 101. The area within the process chamber 101 located under the substrate 100 is provided with a reflecting plate 107 for improving the accuracy of temperature measurement by the optical pyrometers 105.

In this system, at least one of the plurality of optical pyrometers 105 is placed around the edge of the substrate 100, and at least one of the plurality of optical pyrometers 105 is placed in the center portion of the substrate 100. Each of the optical pyrometers 105 is associated with temperature control of a corresponding portion (that is, a portion facing each said optional pyrometer 105) of the substrate 100.

In rapid thermal processing by the conventional rapid thermal processing system shown in FIG. 21, the substrate 10 and the substrate carrier 2 are processed under heat from a processing atmosphere (an atmosphere within the process chamber) and the heating unit 4. Specifically, when the substrate 10 is subjected to an oxidation processing or an oxynitriding processing by the thermal processing, the substrate carrier 2 is also subjected simultaneously to the oxidation processing or the oxynitriding processing. If the oxidation or oxynitriding processing is carried out at a relatively low temperature of about 700 to 900° C. or in an atmosphere having a weak ability of oxidization or oxynitriding, a change of the substrate carrier 2 by such a processing, in particular a change in the emissivity of the substrate carrier 2 is slight. On the other hand, if the oxidation or oxynitriding processing is carried out at a relatively high temperature of 950° C. or more or in an atmosphere having a relatively strong ability of oxidization or oxynitriding, the substrate carrier 2 is oxidized or oxynitrided by such a processing to change the properties of the substrate carrier 2, in particular the emissivity thereof. Thus, the optical pyrometer 5 provided around the edge of the substrate 10 will misconceive of the change in the emissivity of the substrate carrier 2 as a change in temperature. As a result of this, the optical pyrometer 5 determines that the temperature around the edge of the substrate 10 is changed with time, and then the determined temperature is transferred to the control system 6. Accordingly, although the actual temperature of the substrate 10 is not changed at all, the thermal processing for the edge of the substrate 10 and its vicinity is changed with time.

On the other hands, the tenth embodiment is characterized in that in the rapid thermal processing system shown in FIG. 1A, the substrate 100 is subjected to rapid thermal processing under a reduced pressure to measure the temperature dependence quantity (the physical quantity of the substrate 100 varying depending on the processing temperature of the rapid thermal processing), specifically the thickness of an oxide film formed on the substrate 100 by oxidation under a reduced pressure (for example, about 1300 Pa) and subsequently temperature shifts of the individual optical pyrometers 105 are independently corrected based on the measured thickness of the oxide film. Herein, if the substrate 100 is made of, for example, silicon, the thickness of the oxide film described above is the thickness of a film formed by thermally oxidizing silicon (a SiO₂ film). Hereinafter, the characteristic of the tenth embodiment will be described in detail with reference to the accompanying drawings.

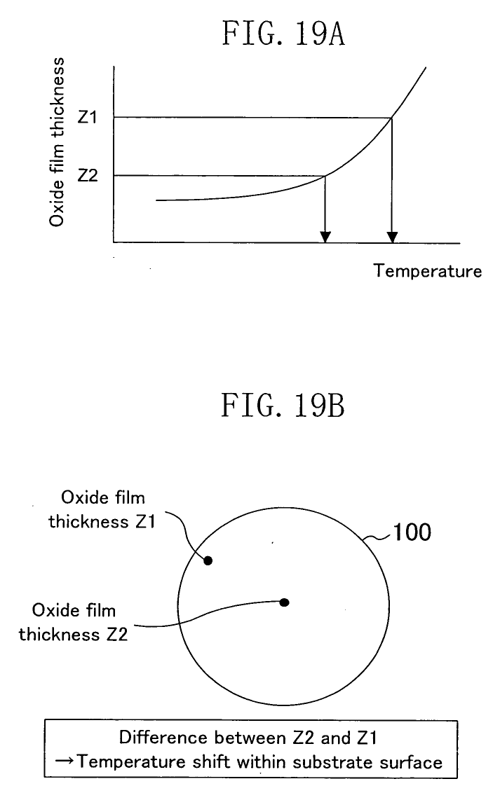

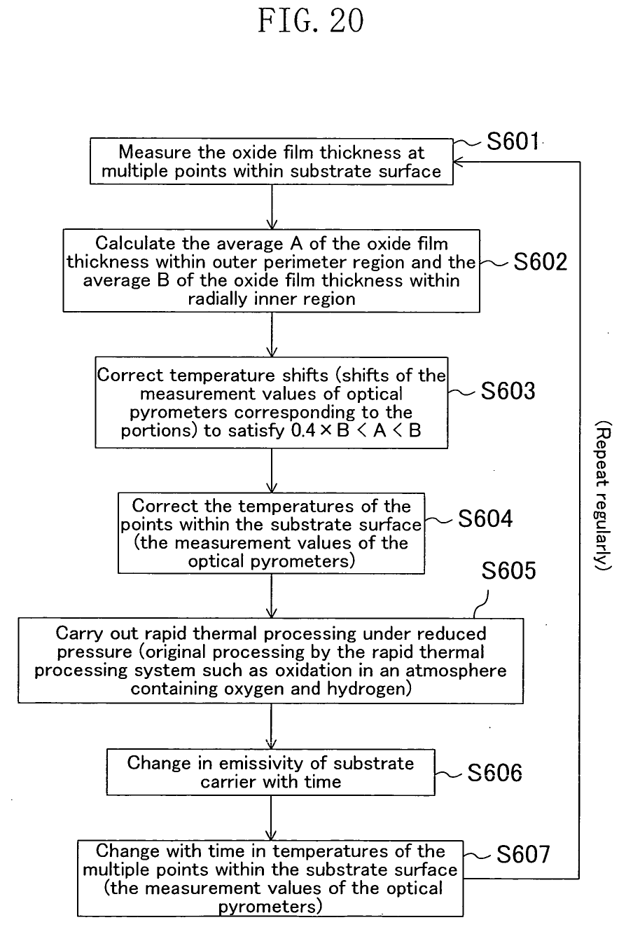

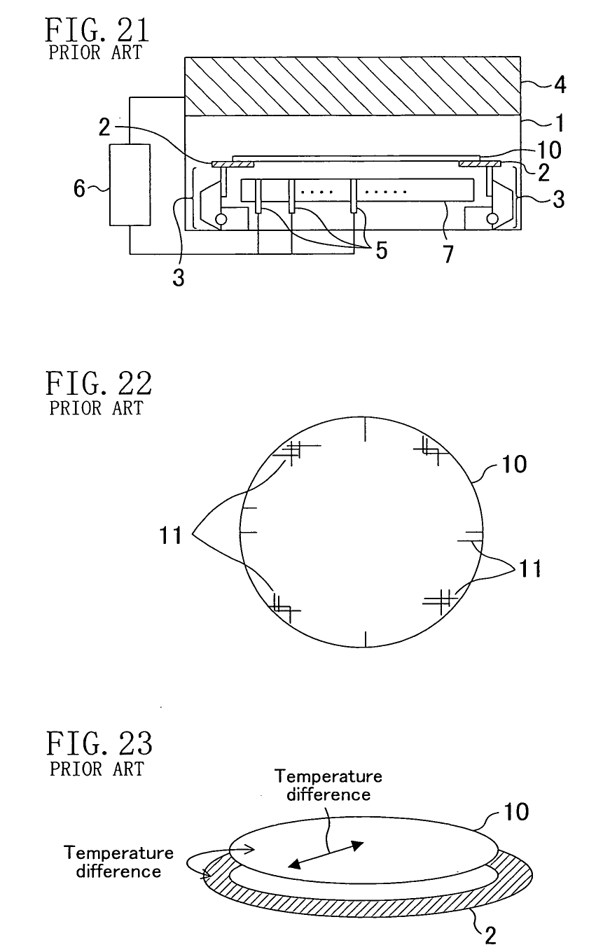

FIGS. 19A and 19B are a graph and a view for describing the characteristic of the tenth embodiment, and FIG. 20 is a flowchart of the temperature adjustment method of the tenth embodiment.

The thickness of the oxide film is uniquely determined by the temperature. Therefore, as shown in FIGS. 19A and 19B, if there is a difference in the thickness of the oxide film within the surface of the substrate 100, the difference corresponds to temperature shift (temperature difference). In the tenth embodiment, utilizing the relation between the difference in the thickness of the oxide film and the temperature shift, the measurement temperatures of the optical pyrometers 105 are corrected.

To be more specific, first, in the step S601, the thicknesses of portions of the oxide film are measured at multiple points within the surface of the substrate 100 during the rapid thermal processing under a reduced pressure. In this measurement, the rapid thermal processing of the substrate 100 is carried out in an oxidizing atmosphere containing no hydrogen, whereby the substrate 100 is oxidized to form an oxide film. This is because in an oxidation under a reduced pressure in an atmosphere containing oxygen and hydrogen, the profile of the thickness of the oxide film within the wafer surface varies freely simply by changing the pressure and thus the thickness of the oxide film is not determined only by the temperature. Moreover, the rapid thermal processing in the step S601 is carried out under a reduced pressure to provide the following effects. Since, in the case of the processing under a reduced pressure, its cooling efficiency after the rapid thermal processing is poorer than processing under an atmospheric pressure, the heat dissipation efficiencies of the substrate 100 and the substrate carrier 102 are significantly lowered. As a result, the substrate carrier 102 having insufficiently been cooled is used for the processing of the next substrate 100, so that the temperature difference between the substrate carrier 102 and the edge of the substrate 100 tends to be large to cause the problem that slips occur easily. On the other hands, in the tenth embodiment, acquirement of the temperature dependence quantity (the thickness of the oxide film) for correcting temperature shifts is carried out under a reduced pressure identical to the actual processing, whereby the accuracy of the temperature correction can be dramatically improved to prevent the above problem, that is, the occurrence of slips.

Next, in the step S602, calculation is made of the average A of the thicknesses of portions of the oxide film measured at multiple arbitrary points located within the outer perimeter region (region a) of the substrate 100 with a width of 10% of the radius (r) of the substrate 100, and of the average B of the thicknesses of portions of the oxide film measured at multiple arbitrary points within a region (region b) of the substrate 100 located radially inwardly from the outer perimeter region (see FIG. 14B in the eighth embodiment). Measurement of the thicknesses of the portions of the oxide film may be made, for example, in such a manner that: of nine points arranged on the main surface of the substrate 100 in a cross arrangement (four points in the region a, and five points in the region b), the average of the measurement values of the four points in the region a is defined as A and the average of the measurement values of the five points in the region b is defined as B (see FIG. 15A in the eighth embodiment); of nine points diametrically arranged on the main surface of the substrate 100 (two points in the region a, and seven points in the region b), the average of the measurement values of the two points in the region a is defined as A and the average of the measurement values of the seven points in the region b is defined as B (see FIG. 15B in the eighth embodiment); or of 49 points concentrically arranged on the main surface of the substrate 100 (24 points in the region a, and 25 points in the region b), the average of the measurement values of the 24 points in the region a is defined as A and the average of the measurement values of the 25 points in the region b is defined as B (see FIG. 15C in the eighth embodiment).

Next, in the step S603, comparison is made between A and B obtained in the step S602, and then temperature shifts (shifts of the measurement values of the optical pyrometers 105) are corrected to satisfy 0.4×B<A<B (see FIG. 14A in the eighth embodiment). Specifically, for example, if B is smaller than A, correction of the temperature shift capable of making B larger than A is made to the optical pyrometer 105 that will affect B. Alternatively, correction of the temperature shift capable of making A smaller than B and larger than 0.4×B may be made to the optical pyrometer 105 that will affect A. Thus, in the step S604, the temperatures of the multiple points within the surface of the substrate 100 (the measurement values of the optical pyrometers 105) are corrected. Note that the temperature shifts of the optical pyrometers 105 are independently corrected.

Thereafter, in the step S605, rapid thermal processing (the original rapid thermal processing by the rapid thermal processing system shown in FIG. 1A) under a reduced pressure is carried out on the substrate 100. During this processing, in the step S606, properties of the substrate carrier 102 (in particular the emissivity) are changed with time, so that in the step S607, the temperatures of the multiple points within the surface of the substrate 100 (the measurement values of the optical pyrometers 105) are also changed with time. To deal with this change, in the tenth embodiment, a sequence of the steps S601 to S607 is regularly carried out, whereby temperature correction is carried out on the optical pyrometers 105. By this procedure, a change with time in the temperature shift of the optical pyrometer 105 disposed around the edge of the substrate 100 can be prevented which results from the change with time in the emissivity or the like of the substrate carrier 102.

As described above, in the tenth embodiment, the substrate 100 is subjected to rapid thermal processing to acquire the thickness of the oxide film, and then temperature shifts of the optical pyrometers 105 are independently corrected based on the acquired thickness of the oxide film. To be more specific, temperature shifts (shifts of the measurement values of the optical pyrometers 105) are corrected to satisfy 0.4×B<A<B (where A is the average of the thicknesses of portions of the oxide film measured at multiple arbitrary points located within the outer perimeter region of the substrate 100 with a width of 10% of the radius (r) of the substrate 100, and B is the average of the thicknesses of portions of the oxide film measured at multiple arbitrary points of a region of the substrate 100 located radially inwardly from the outer perimeter region). Therefore, the temperature shifts within the surface of the substrate 100 caused by the rapid thermal processing can be made uniform with high precision. Accordingly, the temperature controllability can be improved even around the edge of the substrate 100 to suppress slips or the like in the substrate 100, which dramatically boosts yields of devices to be processed.

In the tenth embodiment, since the rapid thermal processing for measuring the thickness of the oxide film as the temperature dependence quantity is carried out under a reduced pressure, the accuracy of the temperature correction can be dramatically improved to more successfully prevent the occurrence of slips or other troubles.

In the tenth embodiment, the step S601 may be carried out using a dummy substrate equivalent to the substrate 100.

Temperature correction in the tenth embodiment may be made either to only the optical pyrometers 105 disposed around the edge of the substrate 100, or to a predetermined number or all of the optical pyrometers 105.

In the tenth embodiment, the boundary between the outer perimeter region (the region a) of the substrate 100 targeted for calculation of the average A of the thickness of the oxide film and the region (the region b) radially inside the substrate 100 targeted for calculation of the average B of the thickness of the oxide film is set at a location radially inwardly from the edge of the substrate 100 by 10% of the radius (r) of the substrate 100. However, the location of the boundary is not limited to any particular position.

In the tenth embodiment, temperature shifts are corrected to satisfy 0.4×B<A<B. In this correction, the lower limit of A (0.4×B in this embodiment) is not limited to any particular value as long as A is smaller than B.

In the tenth embodiment, as the temperature correction method based on the thickness of the oxide film, use is made of the method of the eighth embodiment (the method of using the average A of the thickness of the oxide film measured within the outer perimeter region and the average B of the thickness of the oxide film measured within the radially inner region). Instead of this method, the method of the sixth embodiment (see FIG. 13) may be made as the temperature correction method based on the thickness of the oxide film.

In the tenth embodiment, the substrate 100 is not limited to any particular shape. For example, it may be formed in a disk shape.

In the tenth embodiment, the rapid thermal processing carried out using, for example, the rapid thermal processing system shown in FIG. 1A may be, for example, a processing in an oxygen atmosphere or a nitrogen atmosphere, an oxidation processing in an atmosphere containing at least hydrogen and oxygen (for example, a mixed atmosphere of oxygen and hydrogen or a mixed atmosphere of oxygen, hydrogen and nitrogen), or a processing in an oxidizing atmosphere containing nitrogen (for example, an atmosphere containing NO, N₂O or the like).

The heating unit 104 of the rapid thermal processing system used in the tenth embodiment may operate in a lamp heating method. In this method, a single-sided heating method may be employed in which the substrate 100 is heated only from the upper side thereof, or a double-sided heating method may be employed in which the substrate 100 is heated from the both sides thereof. As a heating lamp, a combination of multiple halogen lamps may be used. To be more specific, a plurality of halogen lamps may be disposed in multiple areas (zones) on the upper side of the substrate 100 (and the lower side of the substrate 100), respectively, and simultaneously the optical pyrometers 105 associated with the halogen lamps may be provided in the respective zones to control each of the halogen lamps based on the measurement temperature of the corresponding optical pyrometer 105. For example, the measurement temperature of the optical pyrometer 105 placed around the edge of the substrate 100 affects, through the control system 106, the setting of power of the heating lamp disposed in the zone around the edge of the substrate 100, while the measurement temperature of the optical pyrometer 105 placed in the center portion of the substrate 100 affects, through the control system 106, the setting of power of the heating lamp disposed in the zone at the center portion of the substrate 100.

In the case of employing the lamp heating method for the heating unit 104 of the rapid thermal processing system used in the tenth embodiment, one or more partitions transmitting light or the like from the heating lamp may be provided between the substrate 100 and the lamp. In such a case, the partition or partitions may be made of quartz or a material containing quartz.

In the rapid thermal processing system used in the tenth embodiment, the plan shape of the substrate carrier 102 is not limited to any particular shape. For example, it may be annular. The substrate carrier 102 may be provided with a shelf for carrying the substrate 100. As the substrate carrier 102, a substrate carrier having resistance to oxidation, that is, the substrate carrier 102 in any of the first to fourth embodiments may be used.

In the rapid thermal processing system used in the tenth embodiment, the substrate carrier 102 is disposed on the rotating unit 103. Alternatively, the substrate carrier 102 may be disposed on another driving mechanism.

In the tenth embodiment, the optical pyrometers 105 may be disposed in an area within the process chamber 101 located under the substrate 100 so that the pyrometers are not in direct contact with the substrate 100. In the case where thermal processing is carried out with no rotation of the substrate 100, that is, the wafer, the optical pyrometers may be provided to be in contact with the substrate 100. In the case where the optical pyrometer 105 is disposed around the edge of the substrate 100, the optical pyrometer 105 may be disposed, for example, about 5 mm inwardly away from the edge of the substrate 100. Specifically, if the substrate 100 is a wafer having a radius of 100 mm, the optical pyrometer 105 may be disposed about 95 mm away from the center of the wafer.

1. A rapid thermal processing system for carrying out rapid thermal processing on a substrate,
wherein the system comprises a substrate carrier for supporting the substrate, and
the substrate carrier has oxidation resistance.

2. The system of claim 1,
wherein the substrate carrier contains an element forming the substrate.

3. The system of claim 1,
wherein an element forming the substrate is silicon.

4. The system of claim 1,
wherein the oxidation resistance is imparted to the substrate carrier by nitriding, oxidizing, or oxynitriding a component of the carrier.

5. The system of claim 1,
wherein the oxidation resistance is imparted only to a portion of the substrate carrier exposed to an atmosphere during the rapid thermal processing.

6. A method for manufacturing a rapid thermal processing system,
wherein the method manufactures the rapid thermal processing system of claim 4, and
the nitriding, oxidation, or oxynitriding of the component of the substrate carrier is carried out using the rapid thermal processing system or another rapid thermal processing system.

7. A temperature adjustment method for adjusting the temperature of a substrate in a rapid thermal processing system for carrying out rapid thermal processing on the substrate,
wherein the rapid thermal processing system comprises: a substrate carrier for supporting the substrate; and a plurality of optical pyrometers for measuring the temperature of the substrate during the rapid thermal processing,
the plurality of optical pyrometers are disposed at least in a center portion and an edge portion of the substrate so that the pyrometers are not in direct contact with the substrate, and
the temperature adjustment method comprises the steps of
acquiring the quantity of temperature dependence by carrying out rapid thermal processing on the substrate; and
independently correcting temperature shifts of the individual optical pyrometers based on the acquired quantity of temperature dependence.

8. The method of claim 7,
wherein the quantity of temperature dependence is the amount of slips occurring in the substrate.

9. The method of claim 7,
wherein the quantity of temperature dependence is the thickness of a film formed by carrying out rapid thermal processing on the substrate.

10. The method of claim 9,
wherein the step of correcting temperature shifts includes the substep of correcting the temperature shifts to satisfy 0.4×B<A<B (where A is the average thickness of the film measured at multiple points located within an outer perimeter region of the substrate with a width of 10% of the radius of the substrate, and B is the average thickness of the film measured at multiple points within a region of the substrate located radially inwardly from the outer perimeter region).

11. The method of claim 7,
wherein the step of acquiring the quantity of temperature dependence includes the substep of carrying out rapid thermal processing on the substrate under a reduced pressure.

12. The method of claim 9,
wherein the film is an oxide film, and
the step of acquiring the quantity of temperature dependence includes the substep of carrying out rapid thermal processing on the substrate under a reduced pressure.

13. The method of claim 7,
wherein the substrate carrier has oxidation resistance.
